(19) United States
(12) Patent Application Publication
(10) Pub. No.: US 2025/0324663 A1
(43) Pub. Date: Oct. 16, 2025

(54) SEMICONDUCTOR STRUCTURE AND METHOD FOR FORMING THE SAME

(71) Applicant: Taiwan Semiconductor Manufacturing Company, Ltd., Hsinchu (TW)

(72) Inventors: Ta-Chun LIN, Hsinchu (TW); Hsin-Huang LIN, Taichung City (TW); Chih-Hao CHANG, Chu-Bei City (TW); Jhon-Jhy LIAW, Zhudong Township (TW)

(73) Assignee: Taiwan Semiconductor Manufacturing Company, Ltd., Hsinchu (TW)

(21) Appl. No.: 18/635,310

(22) Filed: Apr. 15, 2024

(51) Int. Cl. H01L 29/417; H01L 21/8234; H01L 27/088; H01L 29/06; H01L 29/08; H01L 29/423; H01L 29/66; H01L 29/775; H01L 29/786

(52) U.S. Cl. CPC H10D 30/6729; H10D 30/014; H10D 30/43; H10D 30/6735; H10D 30/6757; H10D 62/121; H10D 62/151; H10D 64/017; H10D 84/013; H10D 84/038; H10D 84/83

(57) ABSTRACT

A method of forming a semiconductor structure includes forming first and second fin structures in first and second regions of a substrate, respectively; forming first and second source/drain features in the first fin structure; and forming third and fourth source/drain features in the second fin structure. The method further includes forming a first gate structure between the first and second source/drain features; forming a second gate structure between the third and fourth source/drain features; and forming a first trench exposing the first source/drain feature, and forming a second trench exposing the third source/drain feature. The method further includes forming a hard mask layer in the first region of the substrate to cover the first trench; etching the third source/drain feature to extend the second trench; removing the hard mask layer; and depositing a conductive material in the first and second trenches to form first and second source/drain contacts.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometric size (i.e., the smallest component (or line) that can be created using a fabrication process) has decreased. This scaling down process generally provides benefits by increasing production efficiency and lowering associated costs. Such scaling down has also increased the complexity of processing and manufacturing ICs and, for these advancements to be realized, similar developments in IC processing and manufacturing are needed.

As integrated circuit (IC) technologies progress towards smaller technology nodes, multi-gate metal-oxide-semiconductor field effect transistor (multi-gate MOSFET, or multi-gate devices) have been introduced to improve gate control by increasing gate-channel coupling, reducing off-state current, and reducing short-channel effects (SCEs). A multi-gate device generally refers to a device having a gate structure, or portion thereof, disposed over more than one side of a channel region. Gate-all-around (GAA) transistors are examples of multi-gate devices that have become popular and promising candidates for high performance and low leakage applications. A GAA transistor has a gate structure that can extend, partially or fully, around a channel region to provide access to the channel region on two or more sides. While existing GAA transistors may be generally adequate for their intended purposes, they are not entirely satisfactory in all aspects.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1, 2A and 2B are perspective views of a workpiece at various fabrication stages, in accordance with some embodiments of the present disclosure.

FIGS. 3A, 4A, 5A, 6A, 7A, 8A, 9A, 10A, 11A, 12A, 13A, 14A, 15A, and 16A are X-Z cross-sectional views of the workpiece at various fabrication stages along a line A-A′ of FIG. 2A, in accordance with some embodiments of the present disclosure.

FIGS. 3B, 4B, 5B, 6B, 7B, 8B, 9B, 10B, 11B, 12B, 13B, 14B, 15B, and 16B are Y-Z cross-sectional views of the workpiece at various fabrication stages along a line B-B′ of FIG. 2A, in accordance with some embodiments of the present disclosure.

FIGS. 4C, 8C, 9C, and 10C are Y-Z cross-sectional views of the workpiece at various fabrication stages along a line C-C′ of FIG. 2A, in accordance with some embodiments of the present disclosure.

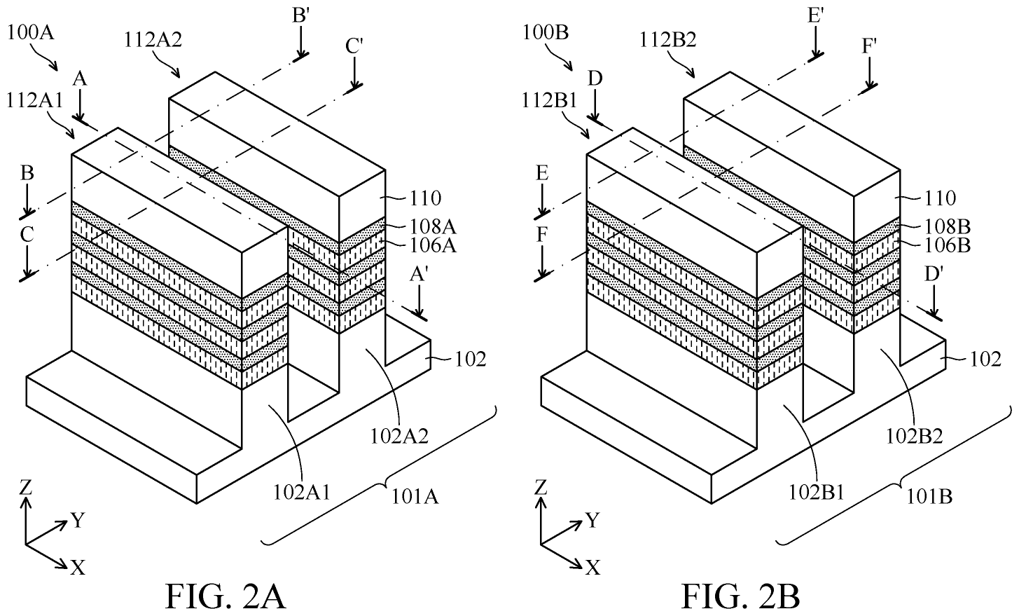

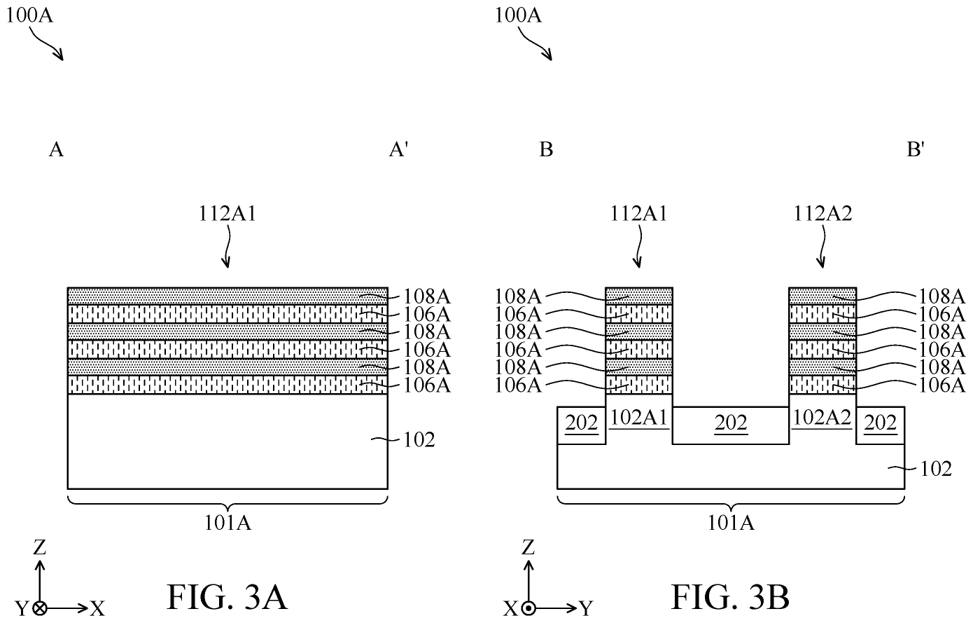

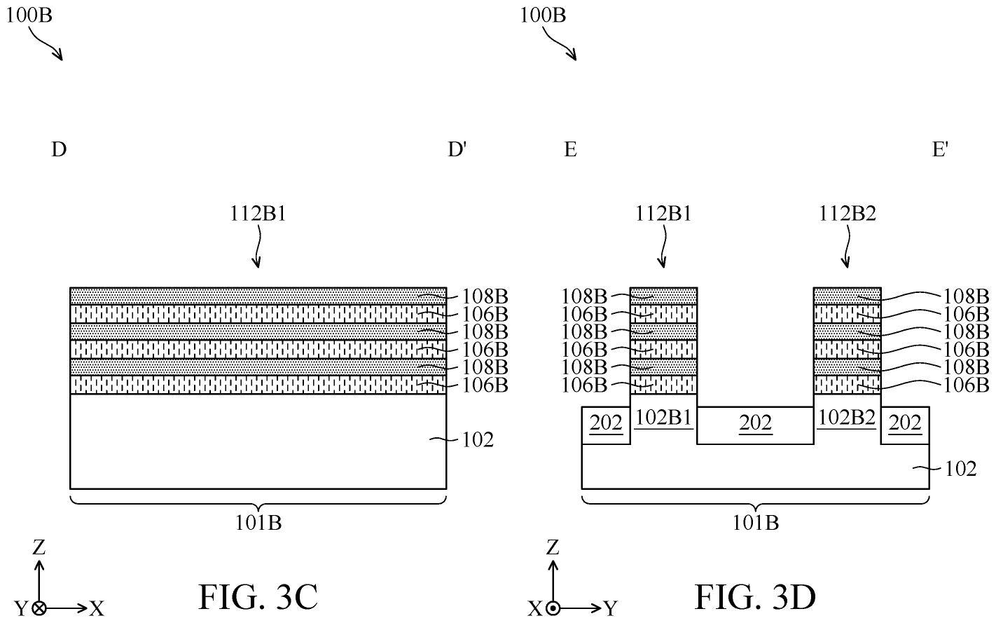

FIGS. 3C, 4D, 5C, 6C, 7C, 8D, 9D, 10D, 11C, 12C, 13C, 14C, 15C, and 16C are X-Z cross-sectional views of the workpiece at various fabrication stages along a line D-D′ of FIG. 2B, in accordance with some embodiments of the present disclosure.

FIGS. 3D, 4E, 5D, 6D, 7D, 8E, 9E, 10E, 11D, 12D, 13D, 14D, 15D, and 16D are Y-Z cross-sectional views of the workpiece at various fabrication stages along a line E-E′ of FIG. 2B, in accordance with some embodiments of the present disclosure.

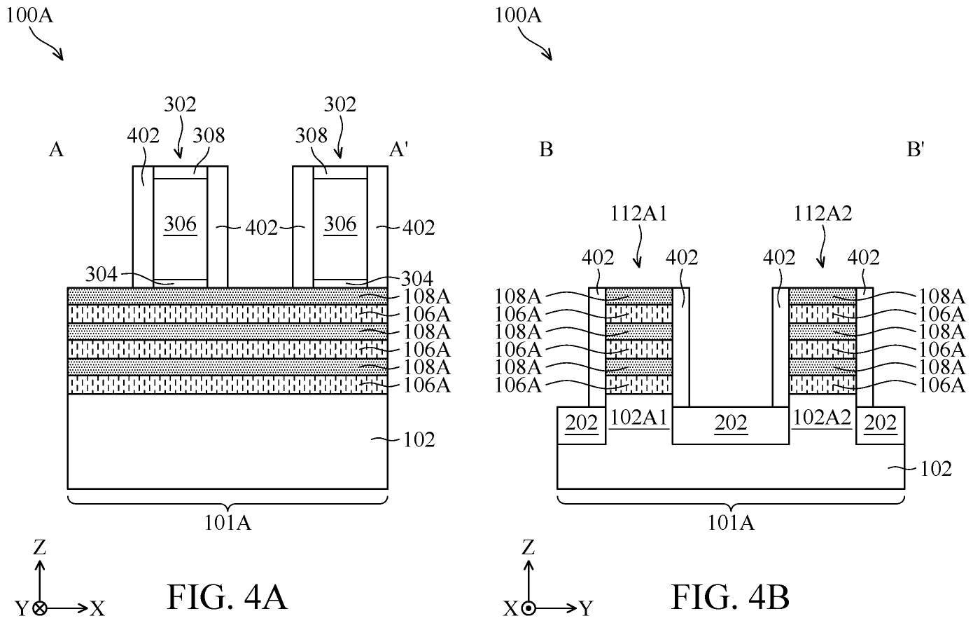

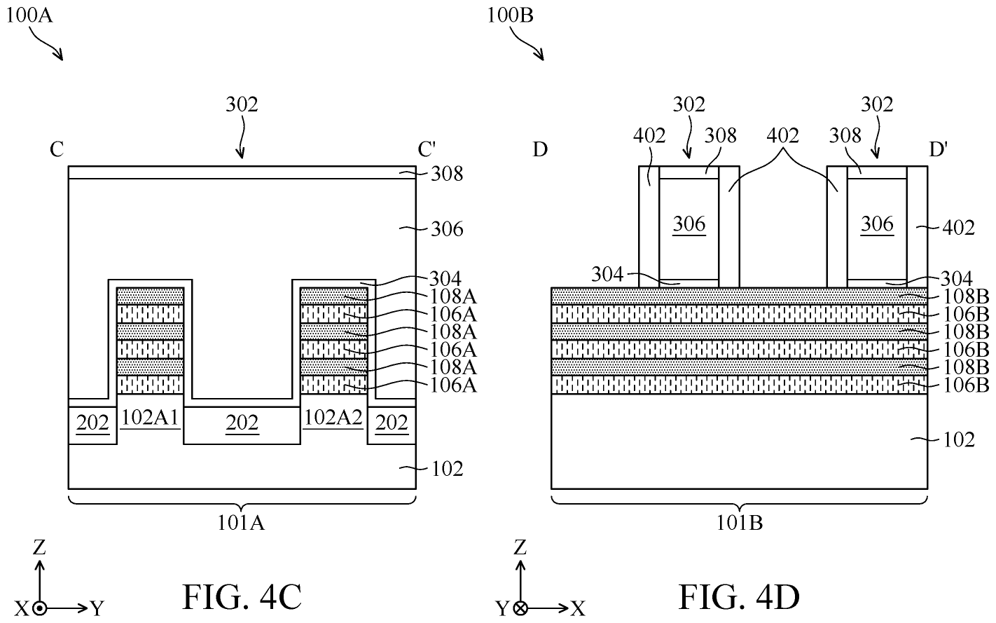

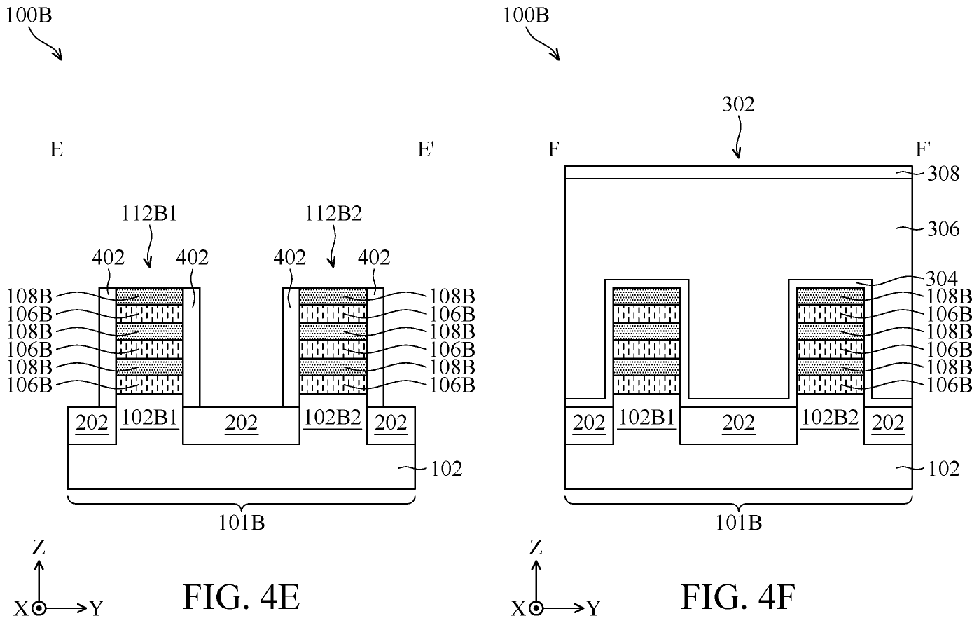

FIGS. 4F, 8F, 9F, and 10F are Y-Z cross-sectional views of the workpiece at various fabrication stages along a line F-F′ of FIG. 2B, in accordance with some embodiments of the present disclosure.

FIGS. 17A, 18A, and 19A are X-Z cross-sectional views of the workpiece at various fabrication stages along a line A-A′ of FIG. 2A, in accordance with some alternative embodiments of the present disclosure.

FIGS. 17B, 18B, and 19B are Y-Z cross-sectional views of the workpiece at various fabrication stages along a line B-B′ of FIG. 2A, in accordance with some alternative embodiments of the present disclosure.

FIGS. 17C, 18C, and 19C are X-Z cross-sectional views of the workpiece at various fabrication stages along a line D-D′ of FIG. 2B, in accordance with some alternative embodiments of the present disclosure.

FIGS. 17D, 18D, and 19D are Y-Z cross-sectional views of the workpiece at various fabrication stages along a line E-E′ of FIG. 2B, in accordance with some alternative embodiments of the present disclosure.

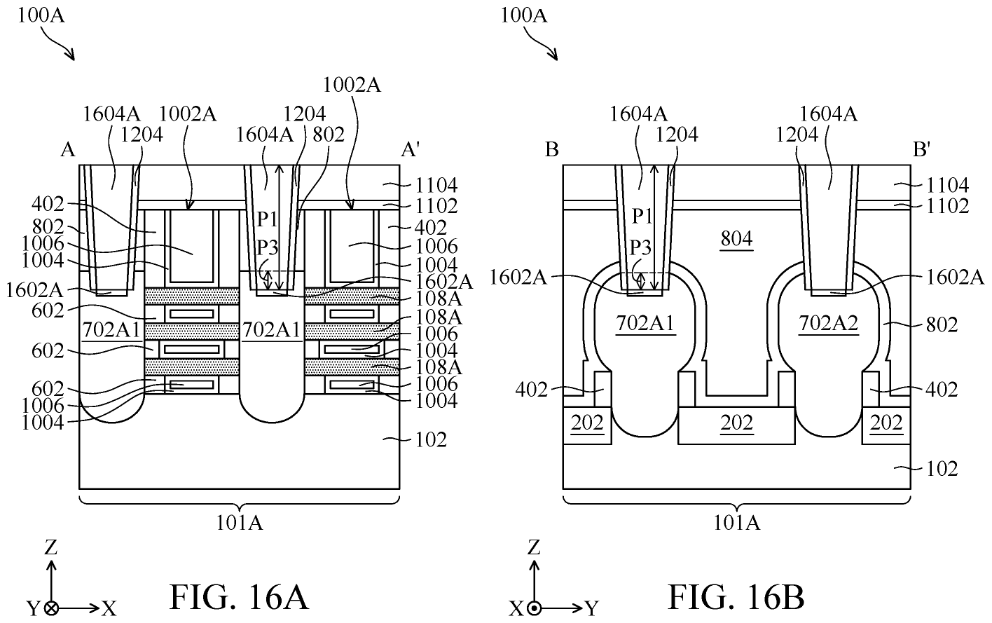

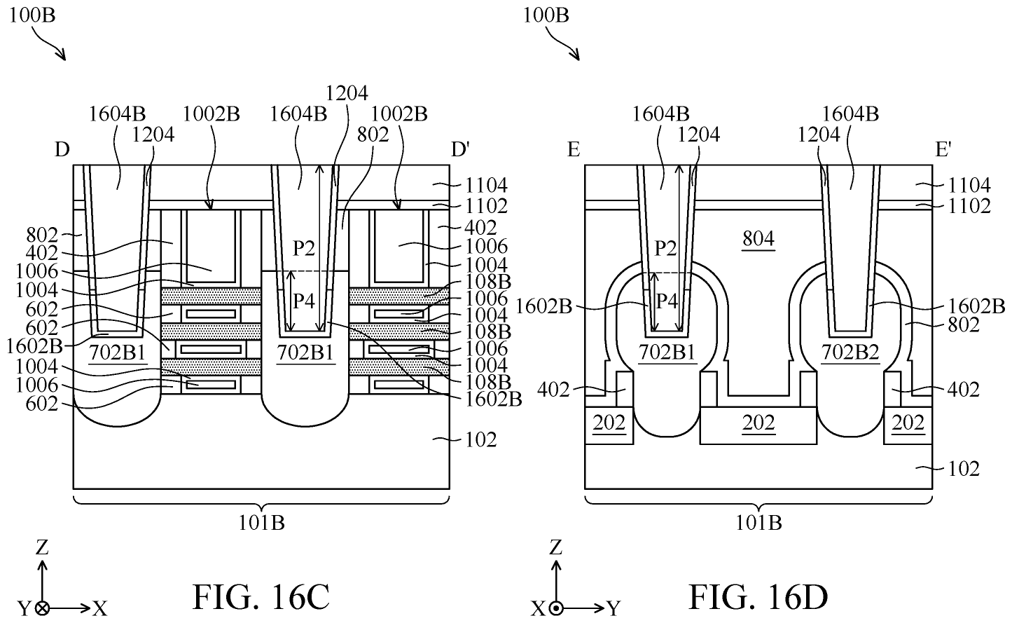

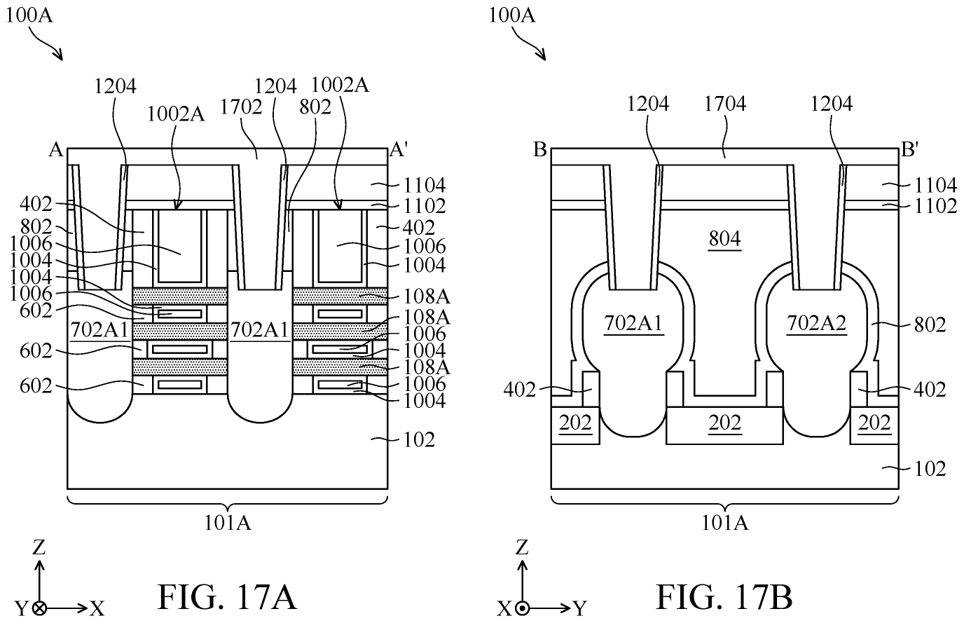

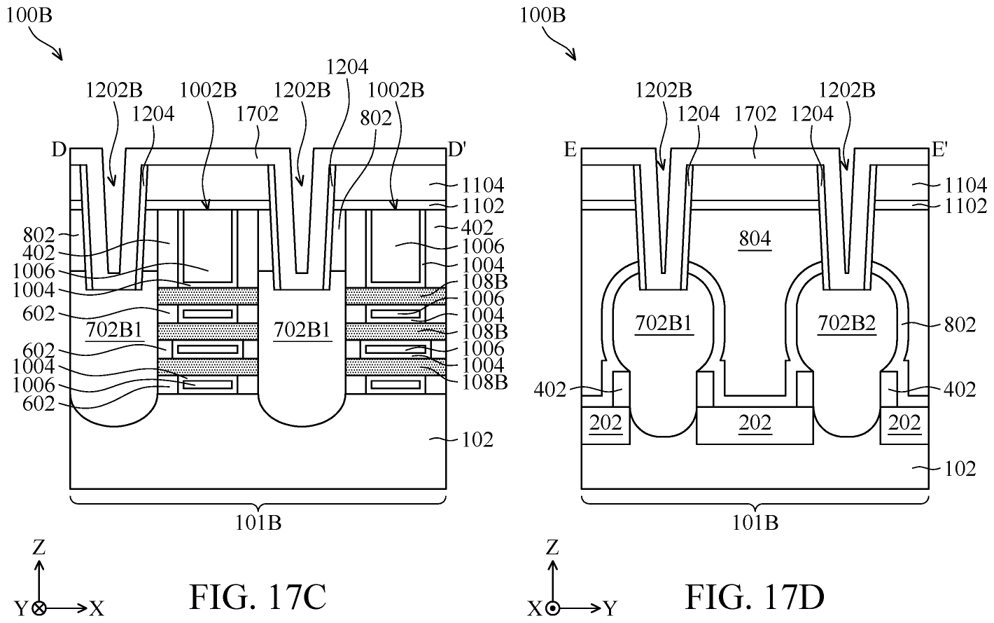

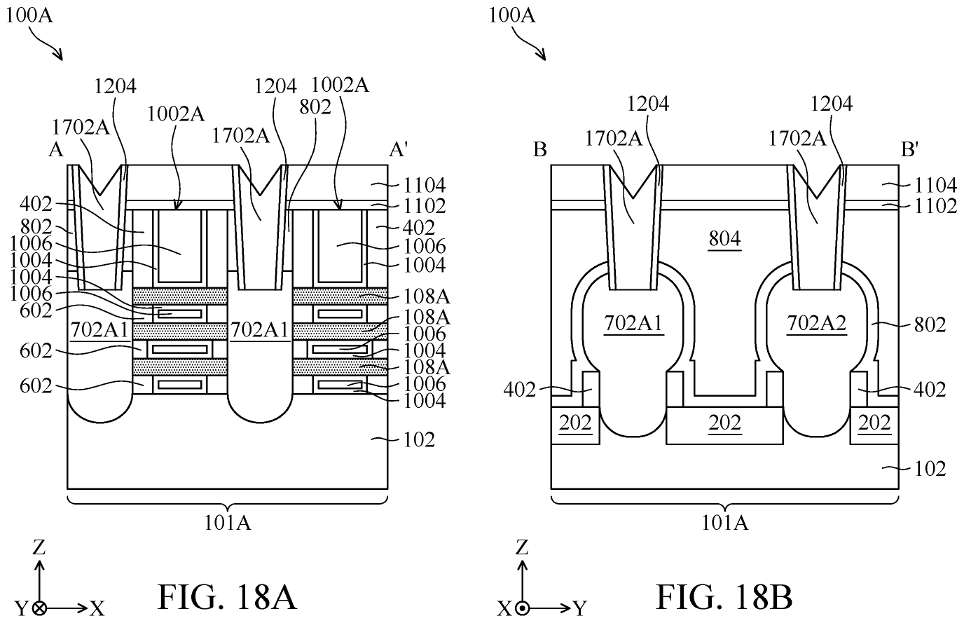

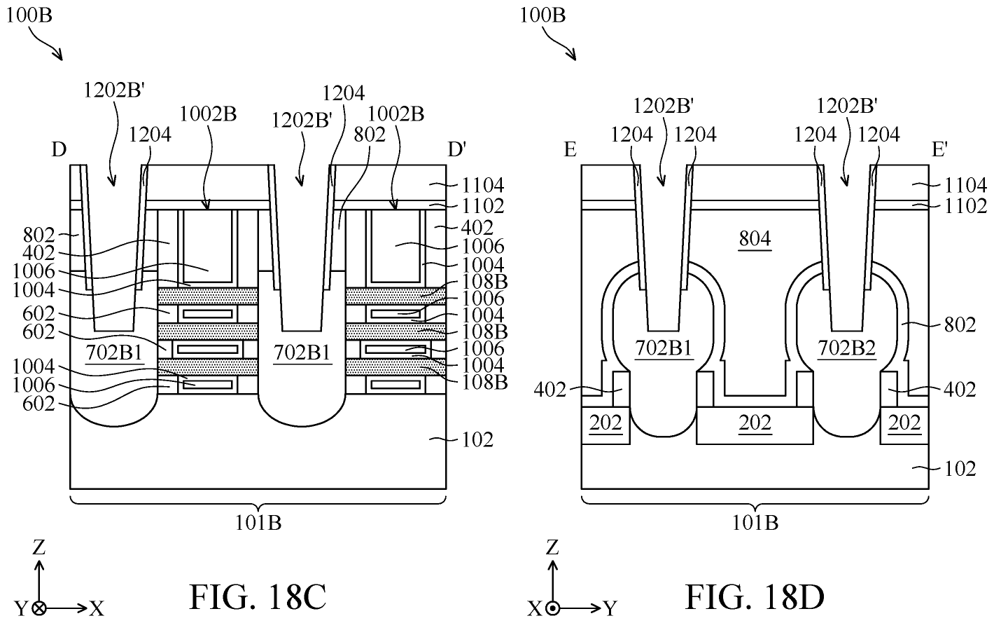

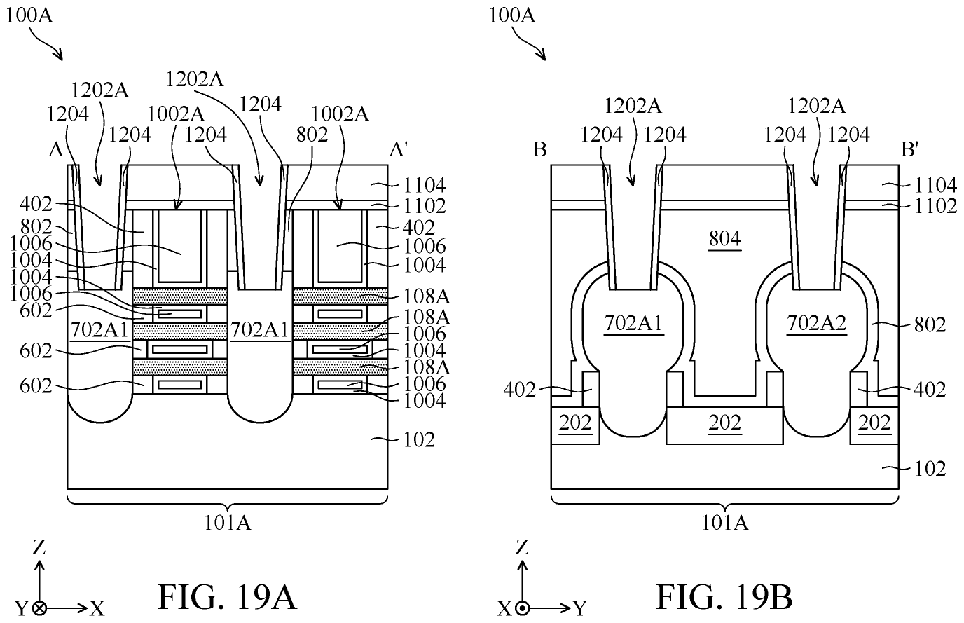

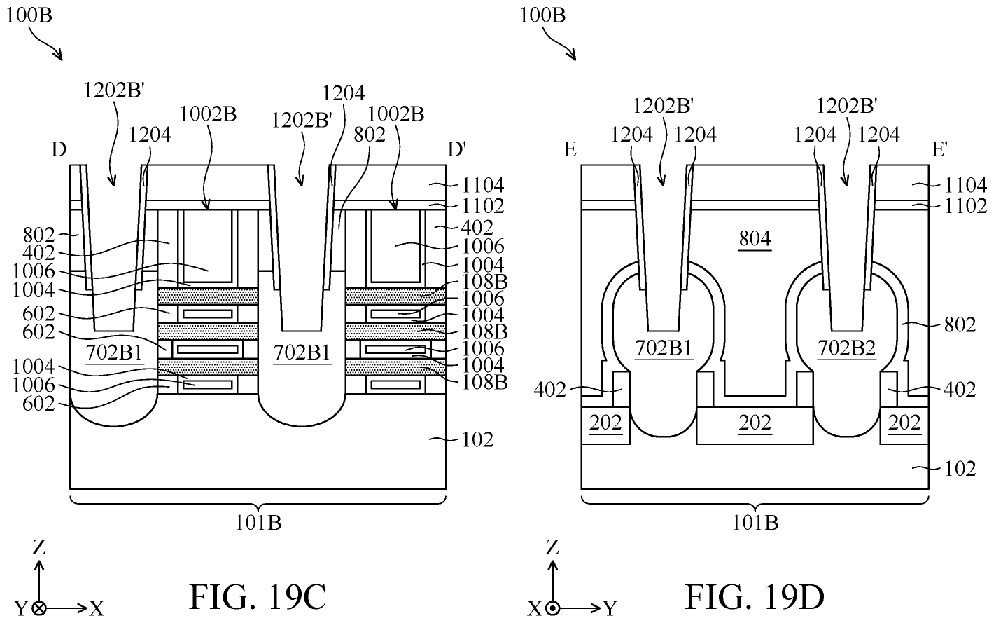

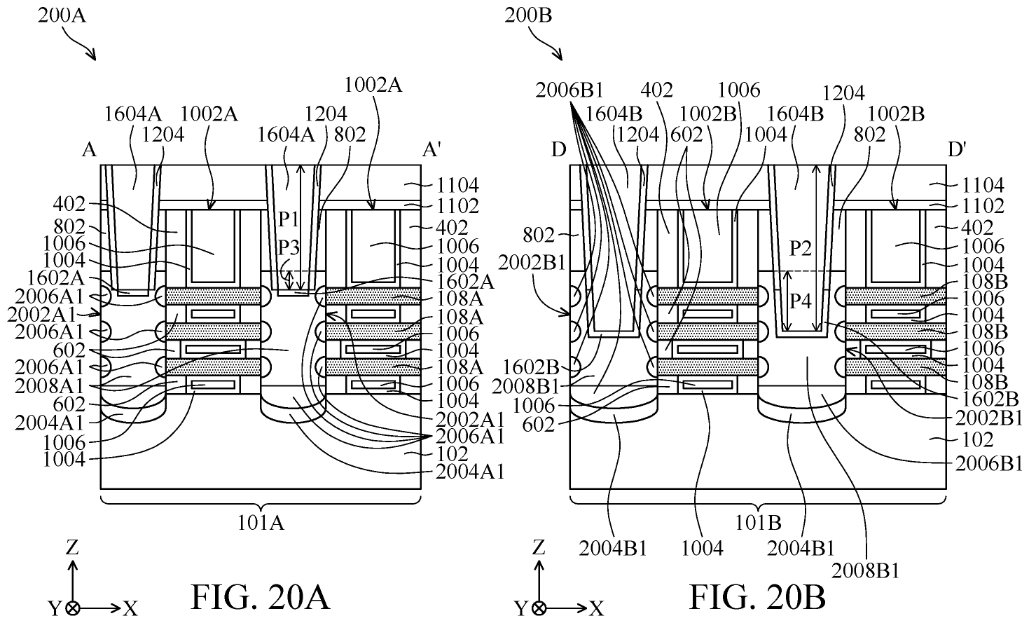

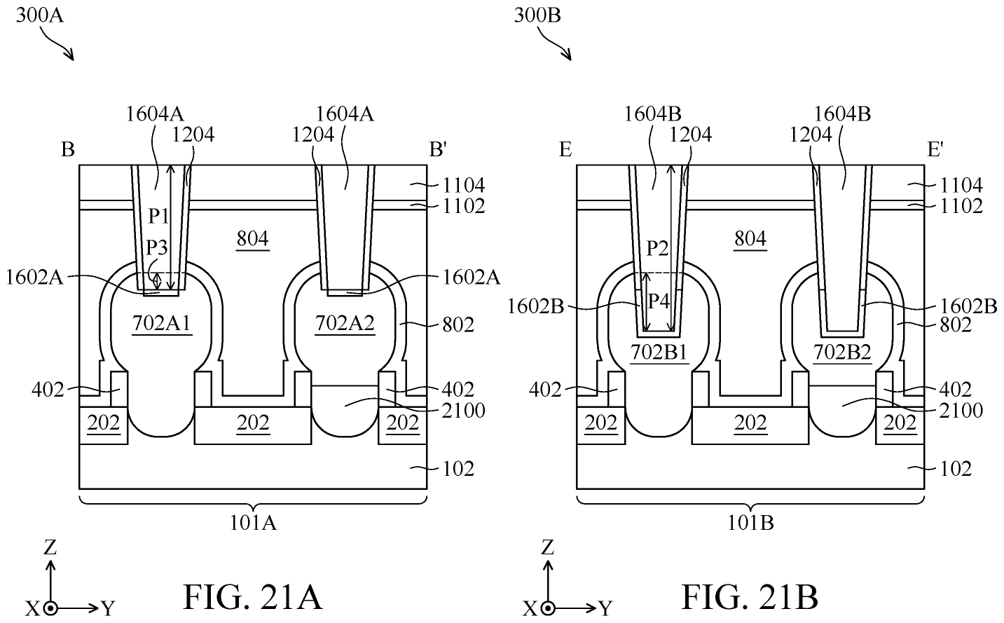

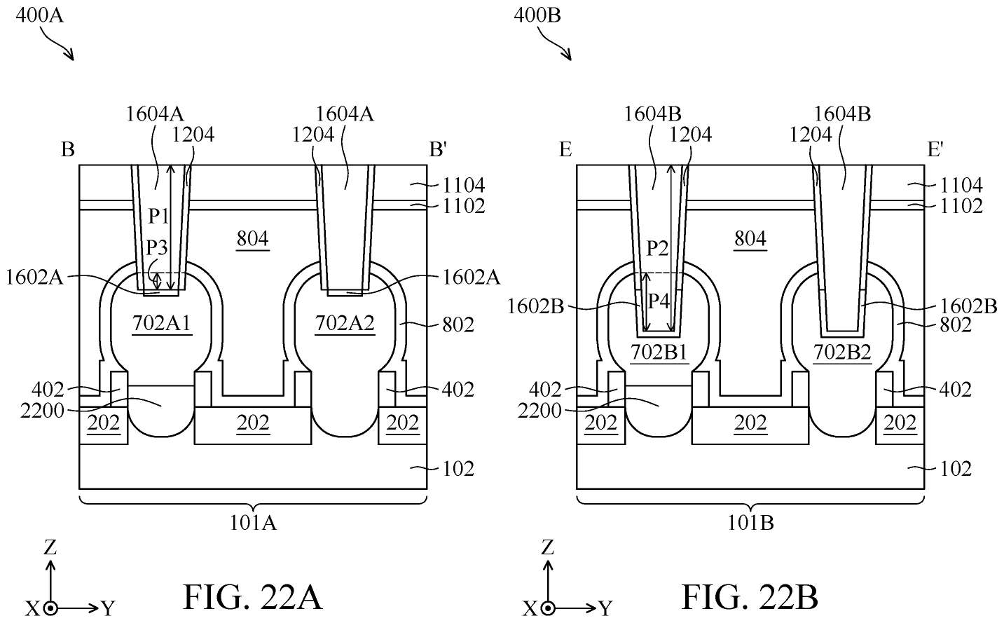

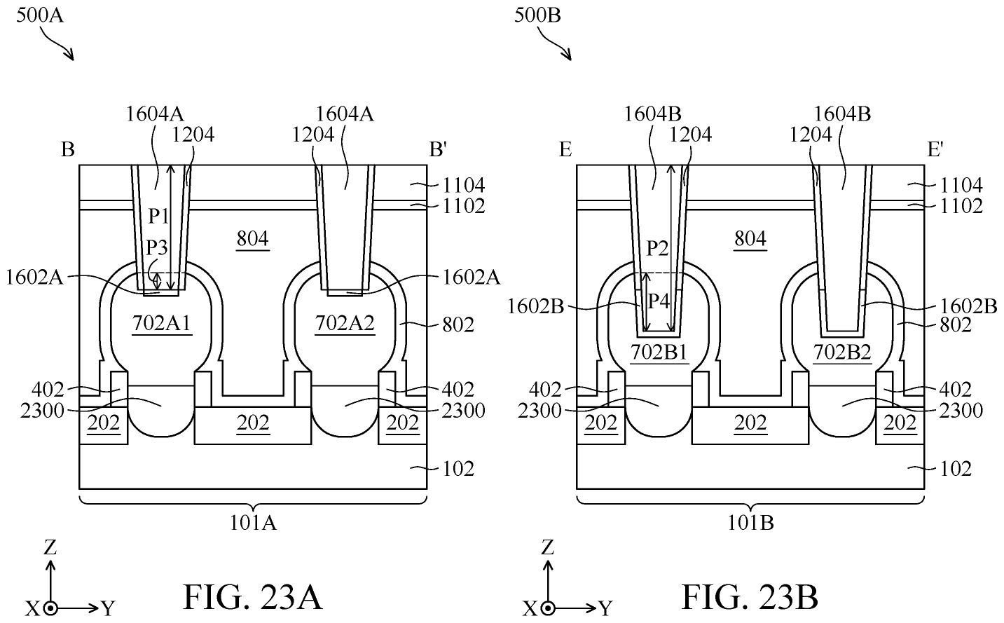

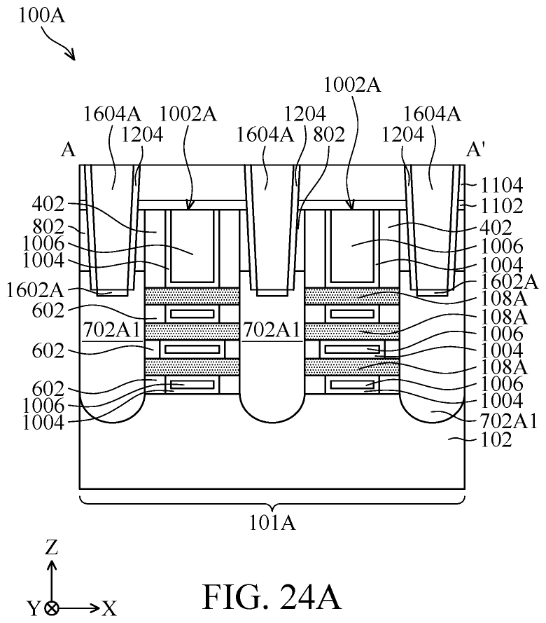

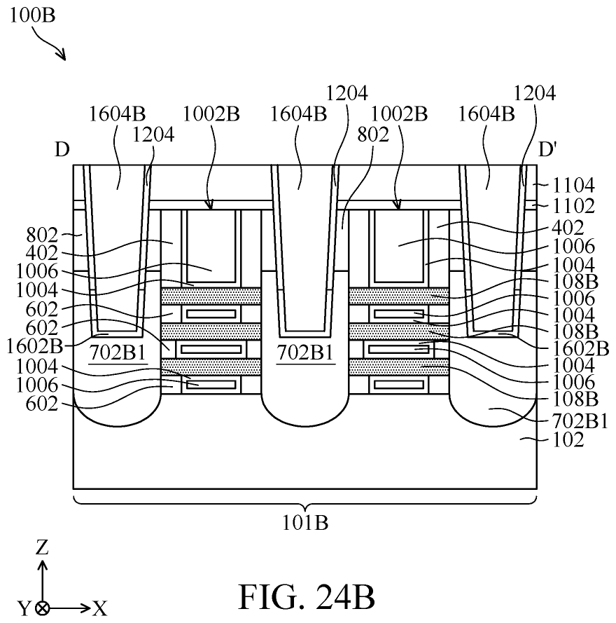

FIG. 20A is an X-Z cross-sectional view of some alternative embodiments of the semiconductor structure of FIG. 16A.

FIG. 20B is an X-Z cross-sectional view of some alternative embodiments of the semiconductor structure of FIG. 16C.

FIGS. 21A, 22A, and 23A are Y-Z cross-sectional views of some alternative embodiments of the semiconductor structure of FIG. 16B.

FIGS. 21B, 22B, and 23B are Y-Z cross-sectional views of some alternative embodiments of the semiconductor structure of FIG. 16D.

FIG. 24A is an X-Z cross-sectional view of some alternative embodiments of the semiconductor structure of FIG. 16A.

FIG. 24B is an X-Z cross-sectional view of some alternative embodiments of the semiconductor structure of FIG. 16C.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The present disclosure is generally related to semiconductor structures, and more particularly to semiconductor structures with field-effect transistors (FETs), such as three-dimensional gate-all-around (GAA) transistors. Generally, a GAA transistor may include a plurality of vertically stacked sheets (e.g., nanosheets), wires (e.g., nanowires), or rods (e.g., nanorods) in a channel region of the transistor, thereby allowing better gate control, lowered leakage current, and improved scaling capability for various IC applications.

The gate-all-around (GAA) transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA transistor.

The critical poly pitch (CPP), which means a pitch between a gate and an adjacent gate, of the GAA transistor is scaled down as the entire dimension of the GAA transistor continue to scale down. In the same wafer or chip, there may be transistors with different CPP for different applications, such as small CPP devices (e.g., transistors with small CPP) and large CPP devices (e.g., transistors with large CPP). In general, since the devices in the same wafer or chip undergo the same process, the depths of the source/drain (S/D) contacts extending in the S/D features are substantially the same in both the small CPP devices and the large CPP devices. However, implementing S/D contacts with the same depth in both the small CPP devices and the large CPP devices may cause some issues.

For example, deeper S/D contacts (i.e., the S/D contacts extending deeper in S/D features) may be required formed in the large CPP devices. However, if the deeper S/D contacts are also formed in the small CPP devices, the deeper S/D contacts may contact the first epitaxial layers (the epitaxial layer grown from the nanostructures) of the S/D features or contact the inner gate portions (i.e., portions of gate structures that formed between the nanostructures), since the S/D features of the small CPP devices have small widths. Since the first epitaxial layers have higher resistance than the second epitaxial layers (the epitaxial layer grown from the first epitaxial layers) of the S/D features, the direct contact between the deeper S/D contacts and the first epitaxial layers increases the contact-to-S/D resistance (Rcsd) and causes current crowding, which also increases the Rcsd. Moreover, the contact between the deeper S/D contacts and the inner gate portions may cause a short-circuit, which decreases the yield. On the other hand, implementing the shallower S/D contacts (i.e., the S/D contacts extending shallower in S/D features) in the large CPP devices cannot provide enough contact area between the S/D contacts and the S/D features, and thus the Rcsd cannot be improved further.

Embodiments of the present disclosure offer advantages over the existing art, though it is understood that other embodiments may offer different advantages, not all advantages are necessarily discussed herein, and no particular advantage is required for all embodiments. For example, embodiments discussed herein include methods and structures that have shallower S/D contacts in the small CPP devices and deeper S/D contacts in the large CPP devices. In this way, it can avoid the contact between the S/D contacts and the first epitaxial layer in the small CPP devices, and thus avoid the increased Rcsd in the small CPP devices. Moreover, it can also avoid the contact between the S/D contacts and the inner gate portions, and thus avoid the negative impact on the yield. On the other hand, since the S/D features of the large CPP devices have large widths, the risk of the S/D contacts coming into contact with the first epitaxial layer of the S/D features and/or the inner gate portions is very low. Therefore, the deeper S/D contacts can be implemented in the large CPP devices and used to increase the contact area between the S/D contacts and the S/D features, and thus the Rcsd in the large CPP devices can be reduced. As a result, the device performances in the small CPP devices and the large CPP devices can be optimized individually and simultaneously.

The various aspects of the present disclosure will now be described in more detail with reference to the figures. For avoidance of doubts, the X-direction, the Y-direction, and the Z-direction in the figures are perpendicular to one another and are used consistently. Throughout the present disclosure, like reference numerals denote like features unless otherwise indicated.

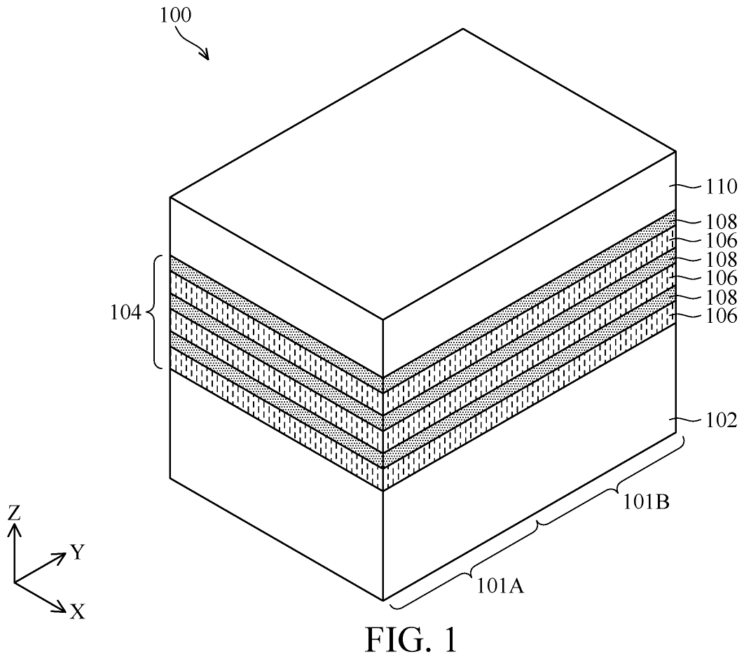

FIGS. 1, 2A and 2B are perspective views of a workpiece 100 at various fabrication stages, in accordance with some embodiments of the present disclosure. Referring to FIG. 1, the workpiece 100 is provided. The workpiece 100 includes a substrate 102 and a stack 104 over the substrate 102. In some embodiments, the substrate 102 contains a semiconductor material, such as bulk silicon (Si). In some other embodiments, the substrate 102 may include other semiconductors such as germanium (Ge), silicon germanium (SiGe), or a III-V semiconductor material. Example III-V semiconductor materials may include gallium arsenide (GaAs), indium phosphide (InP), gallium phosphide (GaP), gallium nitride (GaN), gallium arsenide phosphide (GaAsP), aluminum indium arsenide (AlInAs), aluminum gallium arsenide (AlGaAs), gallium indium phosphide (GaInP), and indium gallium arsenide (InGaAs). The substrate 102 may also include an insulating layer, such as a silicon oxide layer, to have a silicon-on-insulator (SOI) structure or a germanium-on-insulator (GOI) structure.

In some embodiments, the substrate 102 may include one or more well regions for forming different types of devices. For example, the well regions may be n-type well regions doped with an n-type dopant (e.g., phosphorus (P) or arsenic (As)) or p-type well regions doped with a p-type dopant (e.g., boron (B)). The n-type and p-type well regions may be formed by using ion implantation or thermal diffusion. Since the workpiece 100 will be fabricated into a semiconductor structure 100 upon conclusion of the fabrication processes, the workpiece 100 may be referred to as the semiconductor structure 100 as the context requires.

The stack 104 may include semiconductor layers 106 and semiconductor layers 108. In some embodiments, the semiconductor layers 106 and the semiconductor layers 108 are alternatingly stacked in the Z-direction. The semiconductor layers 106 and the semiconductor layers 108 may have different semiconductor compositions. In some embodiments, the semiconductor layers 106 are formed of silicon germanium (SiGe), and the semiconductor layers 108 are formed of silicon (Si). In these embodiments, the additional germanium content in the semiconductor layers 106 allows selective removal or recess of the semiconductor layers 106 without substantial damages to the semiconductor layers 108, so that the semiconductor layers 106 are also referred to as sacrificial layers.

In some embodiments, the semiconductor layers 106 and 108 are epitaxially grown over or on the substrate 102 using an epitaxial growth process such as vapor-phase epitaxy (VPE), metal-organic CVD (MOCVD), molecular beam epitaxy (MBE), although other deposition processes, such as chemical vapor deposition (CVD), low pressure CVD (LPCVD), plasma-enhanced CVD (PECVD), atomic layer deposition (ALD), ultrahigh vacuum CVD (UHVCVD), remote plasma CVD (RPCVD), a combination thereof, or the like, may also be utilized. The semiconductor layers 106 and the semiconductor layers 108 are deposited alternatingly, one-after-another, to form the stack 104. It should be noted that, three layers of the semiconductor layers 106 and three layers of the semiconductor layers 108 are alternately and vertically arranged (or stacked) as shown in FIG. 1, which are for illustrative purposes only and are not intended to be limiting beyond what is specifically recited in the claims. The number of layers depends on the desired number of channel members for the semiconductor device. In some embodiments, there may be from 2 to 10 semiconductor layers 106 alternating with 2 to 10 semiconductor layers 108 in the stack 104.

For patterning purposes, the workpiece 100 may also include a hard mask layer 110 over the stack 104. The hard mask layer 110 may be a single layer structure or a multi-layer structure. In some embodiments, the hard mask layer 110 is a single layer structure and includes a silicon germanium layer. In some embodiments, the hard mask layer 110 is a multi-layer structure and includes a silicon nitride layer and a silicon oxide layer over the silicon nitride layer. In other embodiments, the hard mask layer 110 is a multi-layer structure and includes a silicon germanium layer and a silicon layer over the silicon germanium layer.

Referring to FIGS. 2A and 2B, the workpiece 100 is formed into semiconductor structures 100A and 100B, in accordance with some embodiments. In some embodiments, the semiconductor structure 100A is formed in the region 101A of the workpiece 100, and the semiconductor structure 100B is formed in the region 101B of the workpiece 100. In some embodiments, the substrate 102, the stack 104, and the hard mask layer 110 are patterned to form fin structures 112A1 and 112A2 of the semiconductor structure 100A in the region 101A, and form fin structures 112B1 and 112B2 of the semiconductor structure 100B in the region 101B, as shown in FIGS. 2A and 2B. In some embodiments, the devices (e.g., GAA transistors) formed from the semiconductor structure 100A in the region 101A have smaller critical poly pitch (CPP), and the devices (e.g., GAA transistors) formed from the semiconductor structure 100B in the region 101B have larger CPP, which will be described in more detail below.

In some embodiments, in the semiconductor structure 100A, each of the fin structures 112A1 and 112A2 includes a base portion (base fins 102A1 and 102A2) formed from a portion of the substrate 102 and a stack portion formed from the stack 104 over the base portion, as shown in FIG. 2A. The stack portion includes the semiconductor layers 106A and the semiconductor layers 108A alternately stacked over the substrate 102, wherein the semiconductor layers 106A and 108A are formed from the semiconductor layers 106 and 108, respectively. In some embodiments, the base fins 102A1 and 102A2 protrude from the substrate 102. Each of the fin structures 112A1 and 112A2 extends lengthwise in the X-direction and extends vertically in the Z-direction over the substrate 102, and arranged in the Y-direction. In some embodiments, widths of the fin structures 112A1 and 112A2 along the Y-direction are the same. Although the two fin structures 112A1 and 112A2 are formed and shown herein, more fin structures may be formed, such as three or more fin structures.

In some embodiments, in the semiconductor structure 100B, each of the fin structures 112B1 and 112B2 includes a base portion (base fins 102B1 and 102B2) formed from a portion of the substrate 102 and a stack portion formed from the stack 104 over the base portion, as shown in FIG. 2B. The stack portion includes the semiconductor layers 106B and the semiconductor layers 108B alternately stacked over the substrate 102, wherein the semiconductor layers 106B and 108B are formed from the semiconductor layers 106 and 108, respectively. In some embodiments, the base fins 102B1 and 102B2 protrude from the substrate 102. Each of the fin structures 112B1 and 112B2 extends lengthwise in the X-direction and extends vertically in the Z-direction over the substrate 102, and arranged in the Y-direction. In some embodiments, widths of the fin structures 112B1 and 112B2 along the Y-direction are the same. In some embodiments, widths of the fin structures 112B1 and 112B2 are greater than the fin structures 112A1 and 112A2 along the Y-direction. Although the two fin structures 112B1 and 112B2 are formed and shown herein, more fin structures may be formed, such as three or more fin structures.

The fin structures 112A1, 112A2, 112B1, and 112B2 (may be collectively referred to as fin structures 112) may be patterned using suitable processes including photolithography processes and etching processes. The suitable processes may include double-patterning or multi-patterning processes. For example, in some embodiments, a material layer is formed over a substrate and patterned using a photolithography process. Spacers are formed alongside the patterned material layer using a self-aligned process. The material layer is then removed, and the remaining spacers, or mandrels, may then be used to pattern the fin structures 112A1, 112A2, 112B1, and 112B2 by etching the stack 104 and the substrate 102. The etching process may include dry etching, wet etching, reactive ion etching (RIE), and/or other suitable processes. In some embodiments, the lithography processes include photoresist coating (e.g., spin-on coating), soft baking, mask aligning, exposure, post-exposure baking, developing the photoresist, rinsing, and drying (e.g., hard baking). In some other embodiments, the photolithography processes may be implemented or replaced by other suitable methods, such as maskless photolithography, electron-beam (e-beam) writing, and ion-beam writing.

Referring to FIGS. 3A to 3D, an isolation structure 202 is formed, in accordance with some embodiments. FIGS. 3A and 3B are cross-sectional views of the semiconductor structure 100A along lines A-A′ and B-B′ of FIG. 2A, respectively. FIGS. 3C and 3D are cross-sectional views of the semiconductor structure 100B along lines D-D′ and E-E′ of FIG. 2B, respectively. After the fin structures 112 are formed, the hard mask layer 110 over the fin structures 112 is removed and the isolation structure 202 is formed over the substrate 102. In some embodiments, the isolation structure 202 is formed between the fin structures 112. In other embodiments, the isolation structure 202 is formed around the fin structures 112. More specifically, the isolation structure 202 is formed between and around the base fins (e.g., base fins 102A1, 102A2, 102B1, and 102B2) of the fin structures 112. The isolation structure 202 may also be referred to as a shallow trench isolation (STI) feature.

In some embodiments, a dielectric material for the isolation structure 202 is first deposited over the workpiece 100. Specifically, the dielectric material is deposited and formed over the fin structures 112 and the substrate 102 to cover the fin structures 112 and the substrate 102. In some embodiments, the dielectric material is formed to wrap around the fin structures 112. In some embodiments, the dielectric material may include silicon oxide, silicon nitride, silicon oxynitride, fluorine-doped silicate glass (FSG), a low-k dielectric material, combinations thereof, and/or other suitable materials. Exemplary low-k dielectric materials include carbon doped silicon oxide, Black Diamond® (Applied Materials of Santa Clara, California), xerogel, aerogel, amorphous fluorinated carbon, parylene, BCB-based dielectric material, SiLK (Dow Chemical, Midland, Michigan), polyimide, other low-k dielectric materials, or combinations thereof.

In some embodiments, the dielectric material may be deposited using a deposition process, such as a CVD, a subatmospheric CVD (SACVD), a flowable CVD (FCVD), an ALD, spin-on coating, and/or other suitable process. The deposited dielectric material is then thinned and planarized, for example by a chemical mechanical polishing (CMP) process, until top surfaces of the hard mask layer 110 is exposed (not shown). The planarized dielectric material is further recessed by a dry etching process, a wet etching process, and/or a combination thereof to form the isolation structure 202. In some embodiments, before the formation of the isolation structure 202, a liner layer may be conformally deposited over the substrate 102 using a deposition process, such as CVD, ALD, high-density plasma CVD (HDPCVD), MOCVD, RPCVD, plasma-enhanced CVD (PECVD), LPCVD, atomic layer CVD (ALCVD), atmospheric pressure CVD (APCVD), FCVD, or combinations thereof.

Referring to FIGS. 4A to 4F, dummy gate structures 302 may be formed over the fin structures 112 and over the isolation structure 202, in accordance with some embodiments. FIGS. 4A, 4B, and 4C are cross-sectional views of the semiconductor structure 100A along lines A-A′, B-B′, and C-C′ of FIG. 2A, respectively. FIGS. 4D, 4E, and 4F are cross-sectional views of the semiconductor structure 100B along lines D-D′, E-E′, and F-F′ of FIG. 2B, respectively.

In some embodiments, the dummy gate structures 302 may be configured to extend lengthwise in the Y-direction and wrap around top surfaces and side surfaces of the fin structures 112. In some embodiments, in order to form the dummy gate structures 302, a dummy gate dielectric material for dummy gate dielectric layers 304 is first formed over the fin structures 112 and over the isolation structure 202. In some embodiments, the dummy gate dielectric layer 304 may include, a dielectric material such as a nitride (e.g., silicon nitride, silicon oxynitride), a carbide (e.g., silicon carbide), an oxide (e.g., silicon oxide), or some other suitable materials.

Then, in some embodiments, a dummy gate electrode material for dummy gate electrode layers 306 is formed over the dummy gate dielectric material. The dummy gate electrode material may include a conductive material selected from a group composed of polysilicon, W, Al, Cu, AlCu, Ti, TiAlN, TaC, TaCN, TaSiN, Mn, Zr, TiN, Ta, TaN, Co, Ni, and/or combinations thereof. The dummy gate electrode material and/or the dummy gate dielectric material may be formed by way of a thermal oxidation process and/or a deposition process (e.g., physical vapor deposition (PVD), CVD, PECVD, and ALD).

Afterward, hard mask layers 308 are formed over the dummy gate electrode material. In some embodiments, the hard mask layers 308 may be formed by using photolithography and removal (e.g., etching) processes. In some embodiments, the hard mask layers 308 may include photoresist materials or hard mask materials. In some embodiments, each of the hard mask layers 308 may include multiple layers, such as a silicon nitride layer and a silicon oxide layer. After the formation of the hard mask layers 308, a removal process (e.g., etching) may be performed to remove portions of the dummy gate electrode material and the dummy gate dielectric material that are not directly underlie the hard mask layers 308, thereby forming the dummy gate electrode layers 306 and the dummy gate dielectric layers 304 to constitute the dummy gate structures 302. Each of the dummy gate structures 302 has the dummy gate dielectric layer 304, the dummy gate electrode layer 306, and the hard mask layer 308. The dummy gate dielectric layers 304 may also be referred to as dummy interfacial layers.

The dummy gate structures 302 may undergo a gate replacement process through subsequent processing to form metal gates, such as a high-k metal gate, as discussed in greater detail below. FIGS. 4A and 4D show that each the semiconductor structures 100A and 100B has two dummy gate structures 302. In some embodiments, in the semiconductor structures 100A and 100B, less or more dummy gate structures may be formed for one or more transistors sharing source/drain regions.

Still referring to FIGS. 4A to 4F, after the formation of the dummy gate structures 302, gate spacers 402 are formed on sidewalls of the dummy gate structures 302, and over the top surfaces and on the sidewalls of the fin structures 112, in accordance with some embodiments. In some embodiments, the gate spacers 402 are formed over the top surfaces of the topmost one of the semiconductor layers 108A and the topmost one of the semiconductor layers 108B, as shown in FIGS. 4A and 4D.

The gate spacers 402 may include silicon nitride (Si₃N₄), silicon oxide (SiO₂), silicon carbide (SiC), silicon oxycarbide (SiOC), silicon oxynitride (SiON), silicon carbon nitride (SiCN), silicon oxycarbon nitride (SiOCN), carbon doped oxide, nitrogen doped oxide, porous oxide, or combinations thereof. In some embodiments, the gate spacers 402 include a low-k dielectric material, such as those described herein. The gate spacers 402 may include a single layer or a multi-layer structure.

In some embodiments, the gate spacers 402 may be formed by conformally depositing a spacer layer (containing the dielectric material) over the fin structures 112 and the dummy gate structures 302. Then, an anisotropic etching process is performed to remove top portions of the spacer layer from the top surfaces of the fin structures 112 and the dummy gate structures 302. After the anisotropic etching process, the portions of the spacer layer on the sidewall surfaces of the fin structures 112 and the dummy gate structures 302 substantially remain and become the gate spacers 402. In some embodiments, the anisotropic etching process is a dry (e.g., plasma) etching process. Additionally or alternatively, the formation of the gate spacers 402 may also involve chemical oxidation, thermal oxidation, CVD, PVD, ALD, HDPCVD, MOCVD, RPCVD, PECVD, LPCVD, ALCVD, APCVD, FCVD, and/or other suitable methods. The gate spacers 402 may also be interchangeably referred to as top spacers.

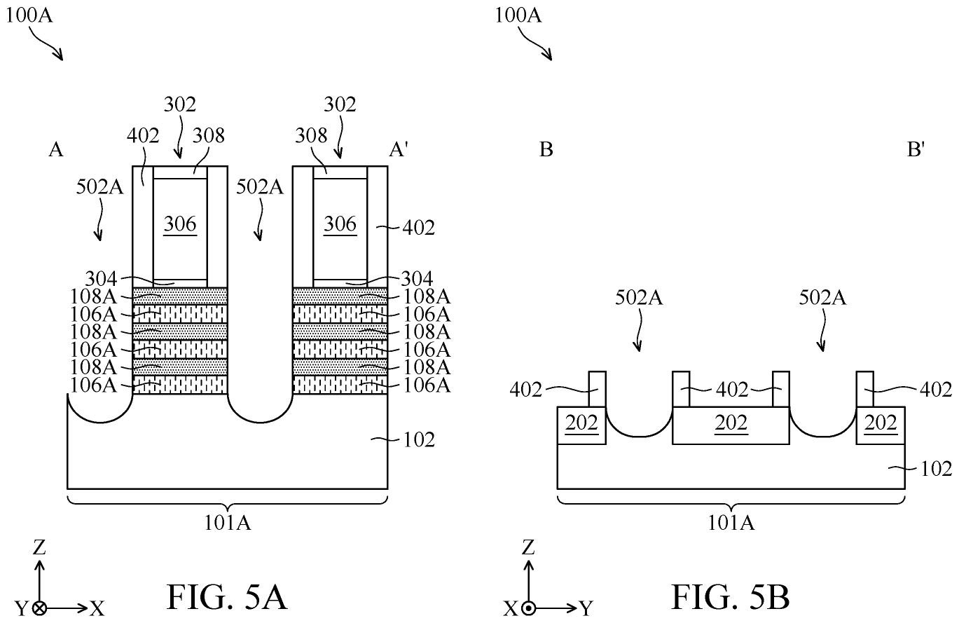

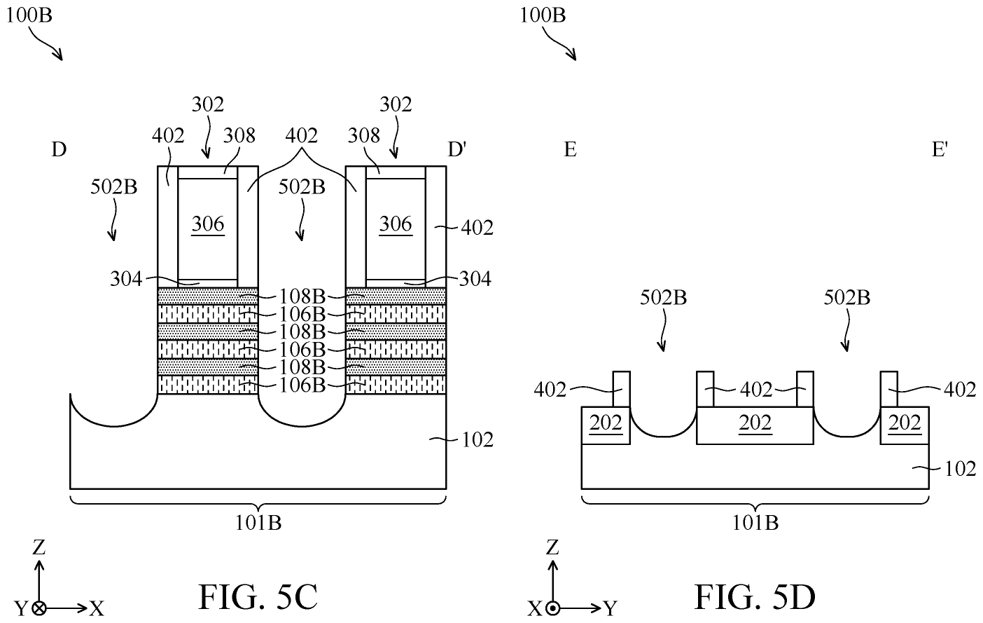

Referring to FIGS. 5A to 5D, the fin structures 112 are recessed to form source/drain trenches in the fin structures 112 (or passing through semiconductor layers 106A, 106B and 108A, 108B) for source/drain regions, in accordance with some embodiments. FIGS. 5A and 5B are cross-sectional views of the semiconductor structure 100A along lines A-A′ and B-B′ of FIG. 2A, respectively. FIGS. 5C and 5D are cross-sectional views of the semiconductor structure 100B along lines D-D′ and E-E′ of FIG. 2B, respectively.

In some embodiments, in the semiconductor structure 100A, the source/drain trenches 502A are formed on opposite sides of the dummy gate structures 302 in the X-direction. In some embodiments, in the semiconductor structure 100B, the source/drain trenches 502B are formed on opposite sides of the dummy gate structures 302 in the X-direction. Specifically, the source/drain trenches 502A may be formed by performing one or more etching processes to remove portions of the semiconductor layers 106A and 108A and the substrate 102 (e.g., base fins 102A1 and 102A2) that do not vertically overlap or not be covered by the dummy gate structures 302 and the gate spacers 402. Similarly, the source/drain trenches 502B may be formed by performing one or more etching processes to remove portions of the semiconductor layers 106B and 108B and the substrate 102 (e.g., base fins 102B1 and 102B2) that do not vertically overlap or not be covered by the dummy gate structures 302 and the gate spacers 402. In some embodiments, a single etchant may be used to remove the semiconductor layers 106 and 108 and the substrate 102. In other embodiments, multiple etchants may be used to perform the etching process. In some embodiments, portions of the substrate 102 are etched, so that the source/drain trenches 502A and 502B (may be collectively referred to as source/drain trenches 502) extend into the substrate and each has a concave surface in the substrate 102, as shown in FIGS. 5A to 5D. In some embodiments, portions of the gate spacers 402 on opposite sidewalls of the fin structures 112 in the Y-direction are removed, as shown in FIGS. 5B and 5D. In these embodiments, the height of the gate spacers 402 on opposite sidewalls of the fin structures 112 in the Y-direction are reduced.

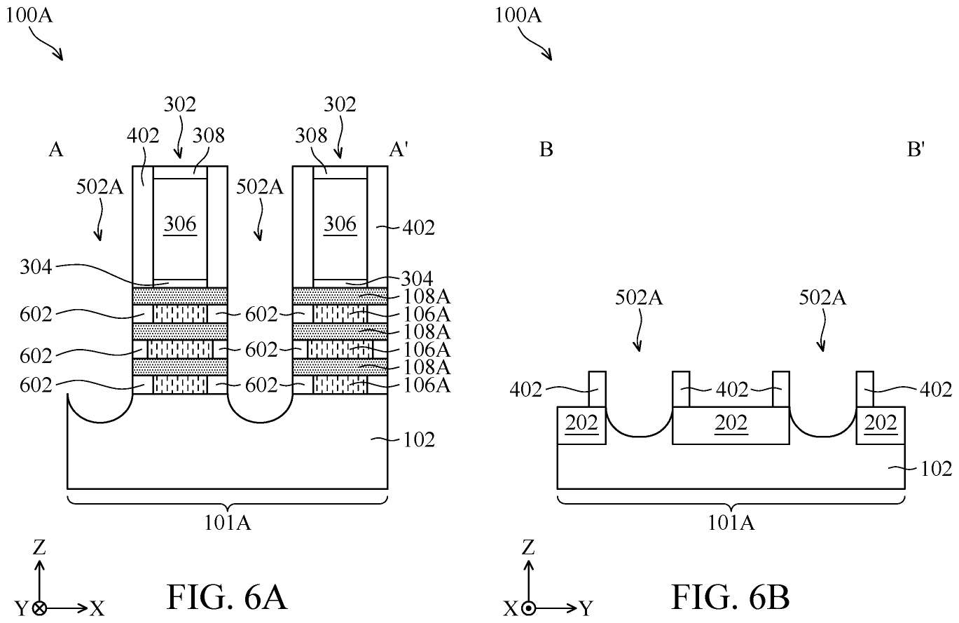

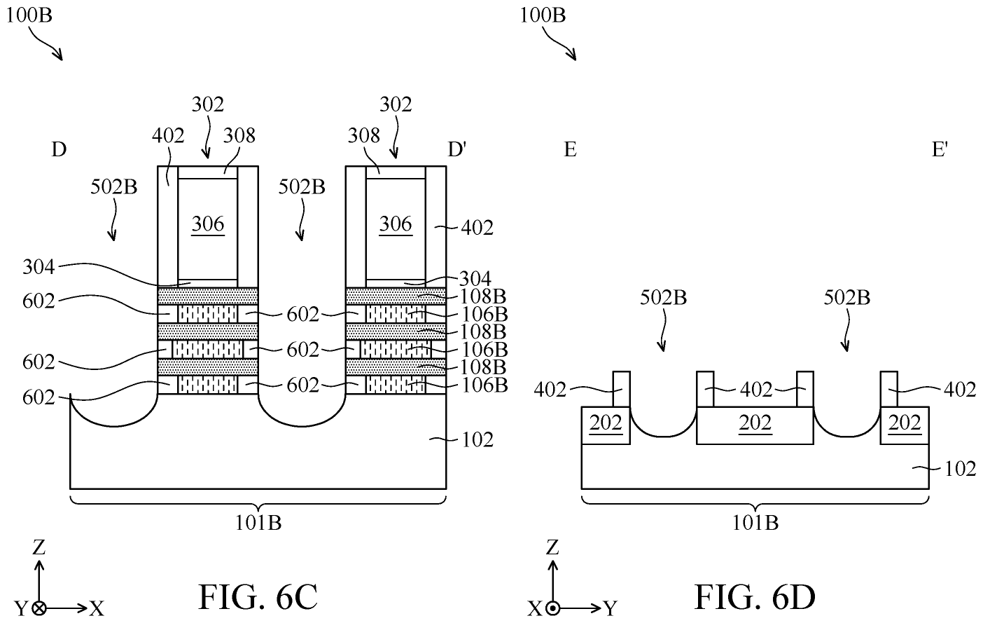

Referring to FIGS. 6A to 6D, the inner spacers 602 are formed between the semiconductor layers 108 (including the semiconductor layers 108A and 108B) as well as between the semiconductor layer 108 and the substrate 102, in accordance with some embodiments. FIGS. 6A and 6B are cross-sectional views of the semiconductor structure 100A along lines A-A′ and B-B′ of FIG. 2A, respectively. FIGS. 6C and 6D are cross-sectional views of the semiconductor structure 100B along lines D-D′ and E-E′ of FIG. 2B, respectively.

In some embodiments, the semiconductor layers 106A exposed in the source/drain trenches 502A and the semiconductor layers 106B exposed in the source/drain trenches 502B are partially recessed through a selective etching process, and the semiconductor layers 108A and 108B are not etched. More specifically, the selective etching process is performed that selectively etches the side portions of the semiconductor layers 106A and 106B below the gate spacers 402 through the source/drain trenches 502A and 502B, with minimal etching (or substantially no etching) of the semiconductor layers 108A and 108B and the substrate 102. After the selective etching process, inner spacer recesses are vertically formed between the semiconductor layers 108 (including the semiconductor layers 108A and 108B) as well as between the semiconductor layers 108 and the substrate 102, below the gate spacers 402. The selective etching process may be a dry etching process, a wet etching process, other suitable etching process, or a combination thereof.

Next, in some embodiments, a spacer layer is conformally formed into the source/drain trenches 502A and 502B and the inner spacer recesses. More specifically, a deposition process is performed to form the spacer layer into the source/drain trenches 502A and 502B and the inner spacer recesses, such as CVD, PVD, ALD, HDPCVD, MOCVD, RPCVD, PECVD, LPCVD, ALCVD, APCVD, FCVD, other suitable methods, or combinations thereof. The spacer layer partially (and, in some embodiments, completely) fills the source/drain trenches 502A and 502B and fully fills the inner spacer recesses. The deposition process is configured to ensure that the spacer layer fills the inner spacer recesses. Furthermore, the spacer layer is also conformally formed on the gate spacers 402 and the isolation structure 202.

The spacer layer may include a material that is different than the materials of the semiconductor layers 108 and the gate spacers 402 to achieve desired etching selectivity during the etching process. In some embodiments, the spacer layer include a dielectric material that includes silicon, oxygen, carbon, nitrogen, other suitable material, or combinations thereof (e.g., silicon oxide (SiO₂), SiON, SiOC, SiCN, SiOCN). In some embodiments, the spacer layer include a low-k dielectric material, such as those described herein. In some embodiments, the spacer layer includes a dielectric material having higher or lower k value (dielectric constant) than the gate spacers 402.

Then, in some embodiments, the inner spacers 602 are formed to fill the inner spacer recesses between the semiconductor layers 108 (including the semiconductor layers 108A and 108B) as well as between the semiconductor layer 108 and the substrate 102. More specifically, an etching process is performed to selectively etch the spacer layer to form the inner spacers 602 with minimal etching (or substantially no etching) of the semiconductor layers 108, the substrate 102, the dummy gate structures 302, and the gate spacers 402. The etching process may be an anisotropic etching process, such that portions of the spacer layer that do not vertically overlap or be covered by the dummy gate structures 302 and the gate spacers 402 are removed. The spacer layer on the gate spacers 402 and the isolation structures 202 are removed.

In some embodiments, sidewalls of the inner spacers 602 are aligned to the sidewalls of the gate spacers 402 and the semiconductor layers 108A or 108B. Therefore, the inner spacers 602 are formed on opposite sides of the dummy gate structure 302. In some embodiments, in the semiconductor structure 100A, the inner spacers 602 are also vertically between the semiconductor layers 108A as well as between the semiconductor layer 108A and the substrate 102. Similarly, in the semiconductor structure 100B, the inner spacers 602 are also vertically between the semiconductor layers 108B as well as between the semiconductor layer 108B and the substrate 102. In some embodiments, the thicknesses of the inner spacers 602 in the X-direction are different. For example, the thicknesses of the second topmost of the inner spacers 602 are less than other inner spacers 602. That is, pairs of inner spacers 602 formed on opposite sides of the second topmost one of the semiconductor layers 106A and 106B in the X-direction have less thicknesses than other inner spacers 602, as shown in FIGS. 6A and 6C. In other words, the second topmost one of the semiconductor layers 106A has a greater length than other semiconductor layers 106A in the X-direction, and the second topmost one of the semiconductor layers 106B has a greater length than other semiconductor layers 106B in the X-direction.

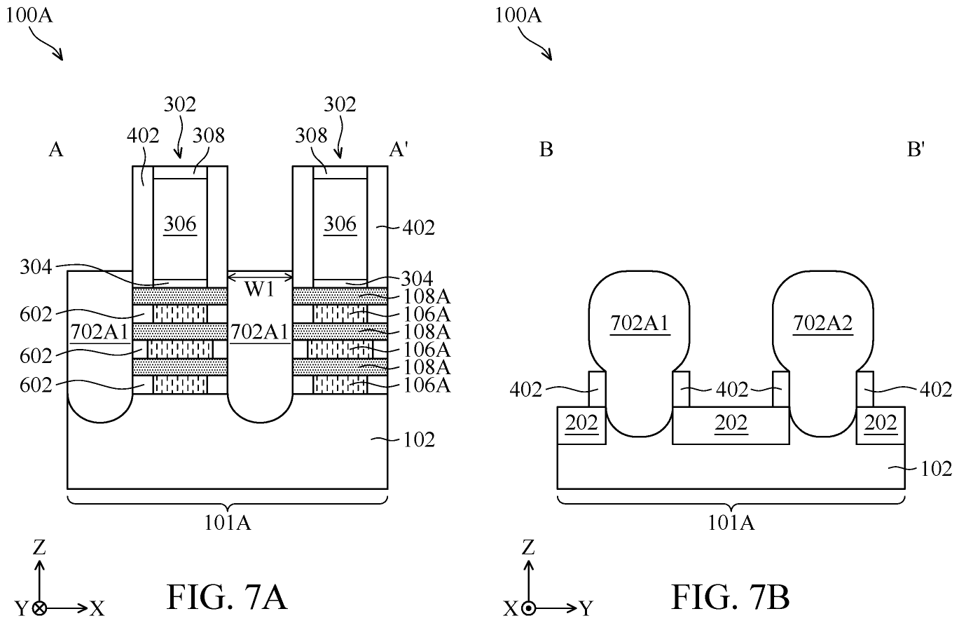

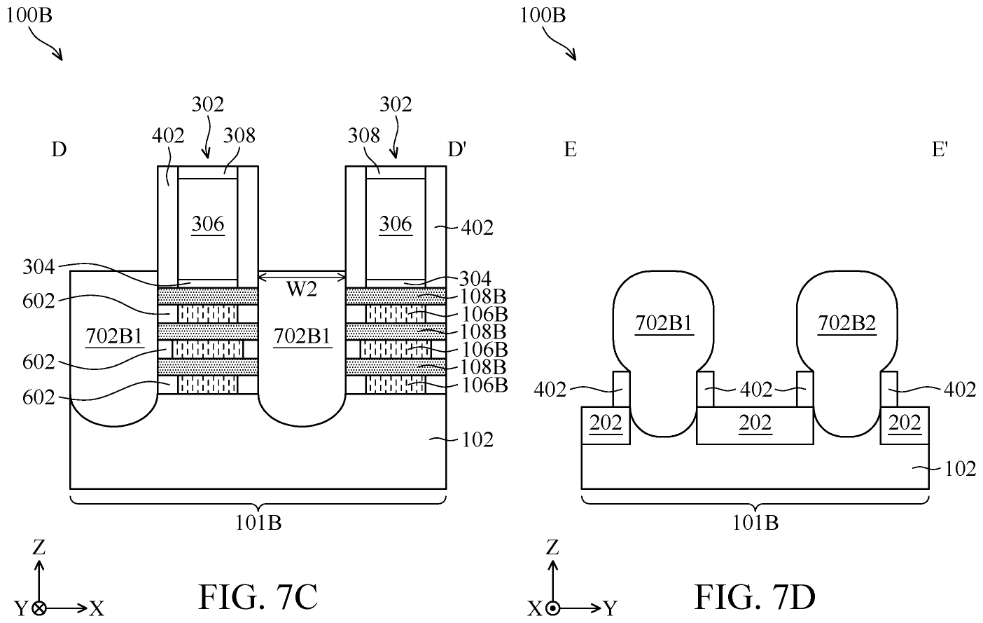

Referring to FIGS. 7A to 7D, source/drain features are formed in the source/drain trenches, in accordance with some embodiments. FIGS. 7A and 7B are cross-sectional views of the semiconductor structure 100A along lines A-A′ and B-B′ of FIG. 2A, respectively. FIGS. 7C and 7D are cross-sectional views of the semiconductor structure 100B along lines D-D′ and E-E′ of FIG. 2B, respectively.

In some embodiments, in the semiconductor structure 100A, source/drain features 702A1 are formed in the source/drain trenches 502A formed in the fin structure 112A1, and source/drain features 702A2 are formed in the source/drain trenches 502A formed in the fin structure 112A2, as shown in FIGS. 7A and 7B. In some embodiments, in the semiconductor structure 100B, source/drain features 702B1 are formed in the source/drain trenches 502B formed in the fin structure 112B1, and source/drain features 702B2 are formed in the source/drain trenches 502B formed in the fin structure 112B2, as shown in FIGS. 7C and 7D.

In some embodiments, since the devices formed from the semiconductor structure 100A has smaller CPP and the devices formed from the semiconductor structure 100B has larger CPP, the devices formed from the semiconductor structure 100B have more space to allocate to source/drain regions. Therefore, the source/drain features 702B1 and 702B2 in the semiconductor structure 100B may have greater widths than the source/drain features 702A1 and 702A2 in the semiconductor structure 100A. For example, the width W2 of the source/drain features 702B1 in the X-direction is greater than the width W1 of the source/drain features 702A1 in the X-direction, as shown in FIGS. 7A and 7C.

In some embodiments, the source/drain features 702A1 and 702A2 are formed on opposite sides of the dummy gate structures 302 in the X-direction. In some embodiments, the source/drain features 702A1 and 702A2 are connected to and in contact with the semiconductor layers 108A in the fin structure 112A1 and 112A2, respectively. That is, the source/drain features 702A1 are attached to opposite sides of the semiconductor layers 108A in the fin structure 112A1, and the source/drain features 702A2 are attached to opposite sides of the semiconductor layers 108A in the fin structure 112A2. In some embodiments, the source/drain features 702B1 and 702B2 are formed on opposite sides of the dummy gate structures 302 in the X-direction. In some embodiments, the source/drain features 702B1 and 702B2 are connected to and in contact with the semiconductor layers 108B in the fin structure 112B1 and 112B2, respectively. That is, the source/drain features 702B1 are attached to opposite sides of the semiconductor layers 108B in the fin structure 112B1, and the source/drain features 702A2 are attached to opposite sides of the semiconductor layers 108B in the fin structure 112B2.

In some embodiments, the source/drain features 702A1 and 702A2 may have top surfaces that extend higher than the top surfaces of the topmost one of the semiconductor layers 108A (e.g., in the Z-direction). Similarly, the source/drain features 702B1 and 702B2 may have top surfaces that extend higher than the top surfaces of the topmost one of the semiconductor layers 108B (e.g., in the Z-direction). In other embodiments, the top surfaces of the source/drain features 702A1 and 702A2 are substantially level with the top surfaces of the topmost one of the semiconductor layers 108A (i.e., substantially coplanar). Similarly, the top surfaces of the source/drain features 702B1 and 702B2 may be substantially level with the top surfaces of the topmost one of the semiconductor layers 108B (i.e., substantially coplanar).

In some embodiments, the semiconductor layers 108A serve as channels to connect one source/drain feature 702A1 (or 702A2) to another source/drain feature 702A1 (or 702A2). Similarly, in some embodiments, the semiconductor layers 108B serve as channels to connect one source/drain feature 702B1 (or 702B2) to another source/drain feature 702B1 (or 702B2). Therefore, the semiconductor layers 108A and 108B may also be referred to as channels, channel layers, or channel members.

One or more epitaxy processes may be employed to grow the source/drain features 702A1, 702A2, 702B1, and 702B2. Epitaxy processes can implement CVD deposition techniques (e.g., VPE, MOCVD, UHVCVD, LPCVD, and/or PECVD), MBE, other suitable selective epitaxial growth (SEG) processes, or combinations thereof. The source/drain features 702A1, 702A2, 702B1, and 702B2 (may be collectively referred to as source/drain features 702) may include any suitable semiconductor materials. In some embodiments, the source/drain features 702A1 and 702B1 are configured to form p-type GAA transistors, and may include silicon (Si), silicon germanium (SiGe), germanium (Ge), silicon germanium carbide (SiGeC), or combinations thereof. In some embodiments, the source/drain features 702A2 and 702B2 are configured to form n-type GAA transistors, and may include silicon (Si), silicon carbide (SiC), silicon phosphide (SiP), silicon arsenide (SiAs), silicon phosphoric carbide (SiPC), or combinations thereof.

The source/drain features 702 may be doped in-situ or ex-situ. For example, the epitaxially grown Si source/drain features may be doped with carbon to form silicon: carbon (Si: C) source/drain features, phosphorous to form silicon: phosphor (Si: P) source/drain features, or both carbon and phosphorous to form silicon phosphoric carbide (SiPC) source/drain features; and the epitaxially grown SiGe source/drain features may be doped with boron. In some embodiments, one or more annealing processes may be performed to activate the dopants in the source/drain features 702. The annealing processes may include rapid thermal annealing (RTA) and/or laser annealing processes.

The source/drain features 702 may also be referred to as source/drain, or source/drain regions. In some embodiments, source/drain feature(s) 702 may refer to a source or a drain, individually or collectively dependent upon the context. In some embodiments, the source/drain features 702A1 and 702B1 for p-type transistors may be referred to as p-type source/drain features, and the source/drain features 702A2 and 702B2 for n-type transistors may be referred to as n-type source/drain features.

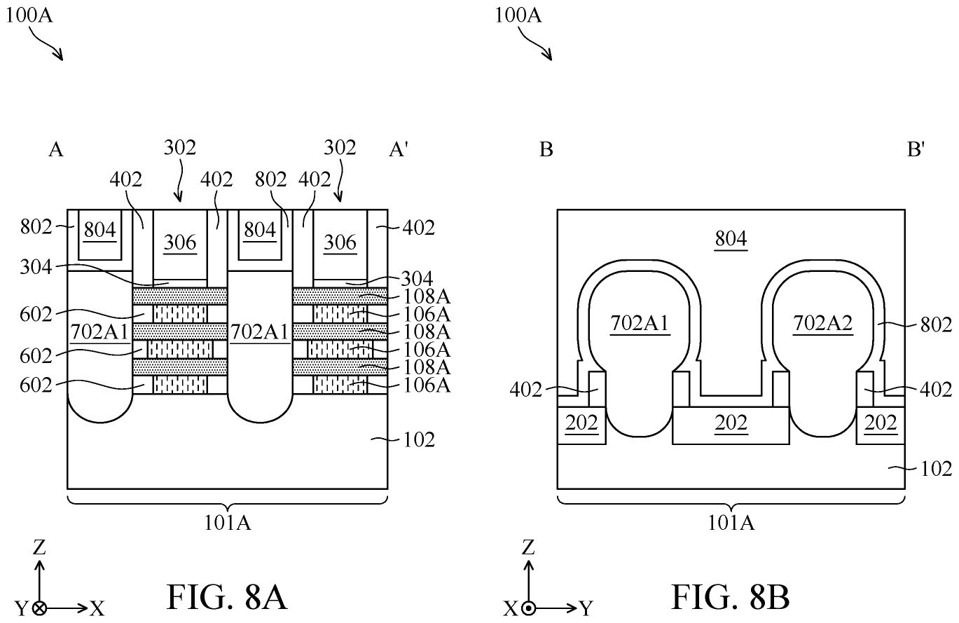

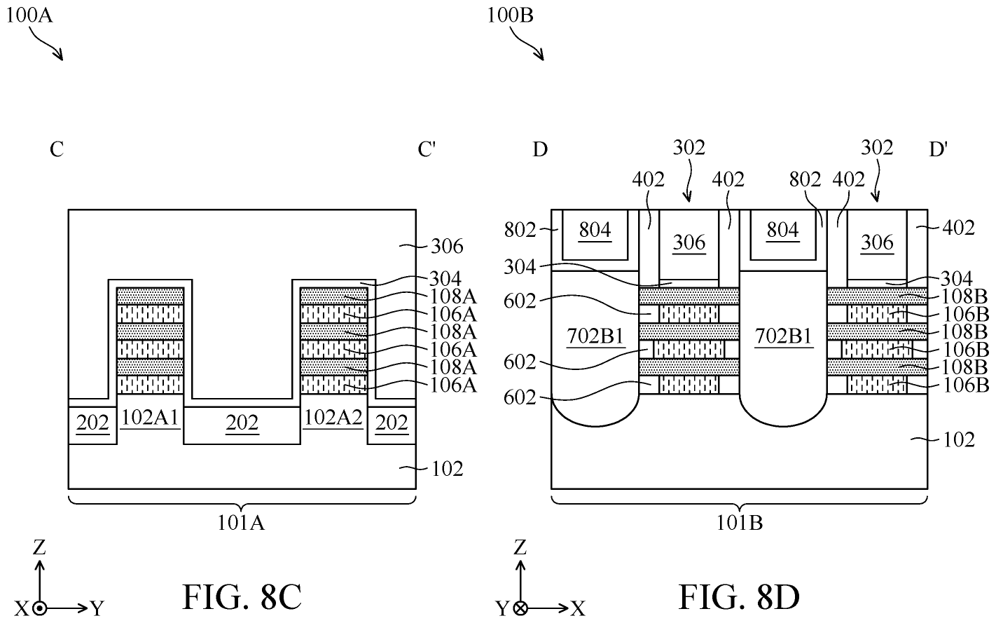

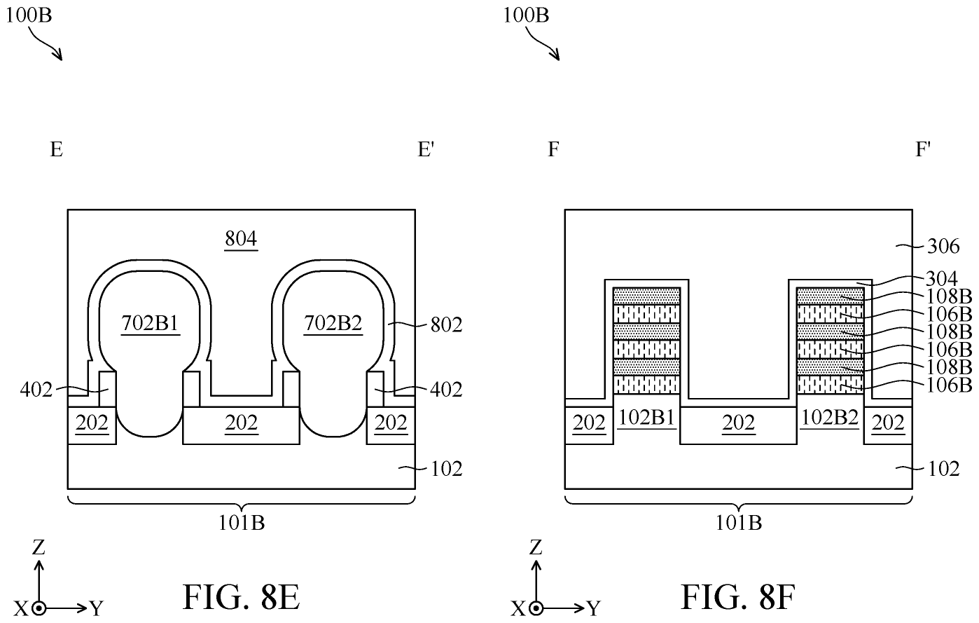

Referring to FIGS. 8A to 8F, a contact etch stop layer (CESL) 802 over the source/drain features 702 and an interlayer dielectric (ILD) layer 804 over the CESL 802 are formed to fill the space between the gate spacers 402, in accordance with some embodiments. FIGS. 8A, 8B, and 8C are cross-sectional views of the semiconductor structure 100A along lines A-A′, B-B′, and C-C′ of FIG. 2A, respectively. FIGS. 8D, 8E, and 8F are cross-sectional views of the semiconductor structure 100B along lines D-D′, E-E′, and F-F′ of FIG. 2B, respectively.

In some embodiments, the CESL 802 is conformally formed on the sidewalls of the gate spacers 402 and over the top surfaces of the source/drain features 702A1, 702A2, 702B1, and 702B2, as shown in FIGS. 8A, 8B, 8D, and 8E. The ILD layer 804 is formed over and between the CESL 802 to fill the spaces between the CESL 802 or between the gate spacers 402.

The CESL 802 may include a material that is different than ILD layer 804. The CESL 802 may include La₂O₃, Al₂O₃, SiOCN, SiOC, SiCN, SiO₂, SiC, ZnO, ZrN, Zr₂Al₃O₉, TiO₂, TaO₂, ZrO₂, HfO₂, Si₃N₄, Y₂O₃, AlON, TaCN, ZrSi, or other suitable materials. The CESL 802 may be formed by CVD, PVD, ALD, HDPCVD, MOCVD, RPCVD, PECVD, LPCVD, ALCVD, APCVD, FCVD, or other suitable methods. The ILD layer 804 may include tetraethylorthosilicate (TEOS) formed oxide, un-doped silicate glass, or doped silicon oxide such as borophosphosilicate glass (BPSG), FSG, phosphosilicate glass (PSG), boron doped silicon glass (BSG), a low-k dielectric material, other suitable dielectric material, or combinations thereof. The ILD layer 804 may be formed by CVD, PVD, ALD, HDPCVD, MOCVD, RPCVD, PECVD, LPCVD, ALCVD, APCVD, FCVD, or other suitable methods.

Subsequent to the deposition of the CESL 802 and the ILD layer 804, a CMP process and/or other planarization process is performed on the CESL 802, the ILD layer 804, the gate spacers 402, and the hard mask layers 308 until the top surfaces of the dummy gate electrode layers 306 are exposed. In some embodiments, portions of the dummy gate electrode layers 306 are removed after the planarization process. In some embodiments, the ILD layer 804 is recessed to a level below the top surfaces of the dummy gate electrode layers 306, and then an ILD protection layer (not shown) is formed over the ILD layer 804 to protect the ILD layer 804 from subsequent etching processes. As such, the ILD layer 804 is surrounded by the CESL 802 and the ILD protection layer. In some embodiments, the ILD protection layer includes a material that is the same as or similar to that in the CESL 802.

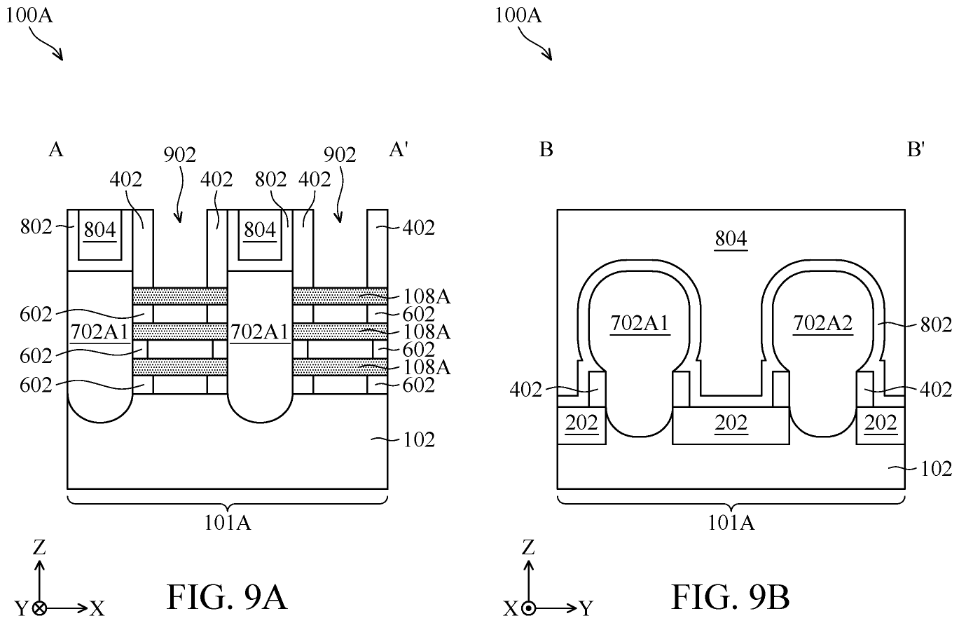

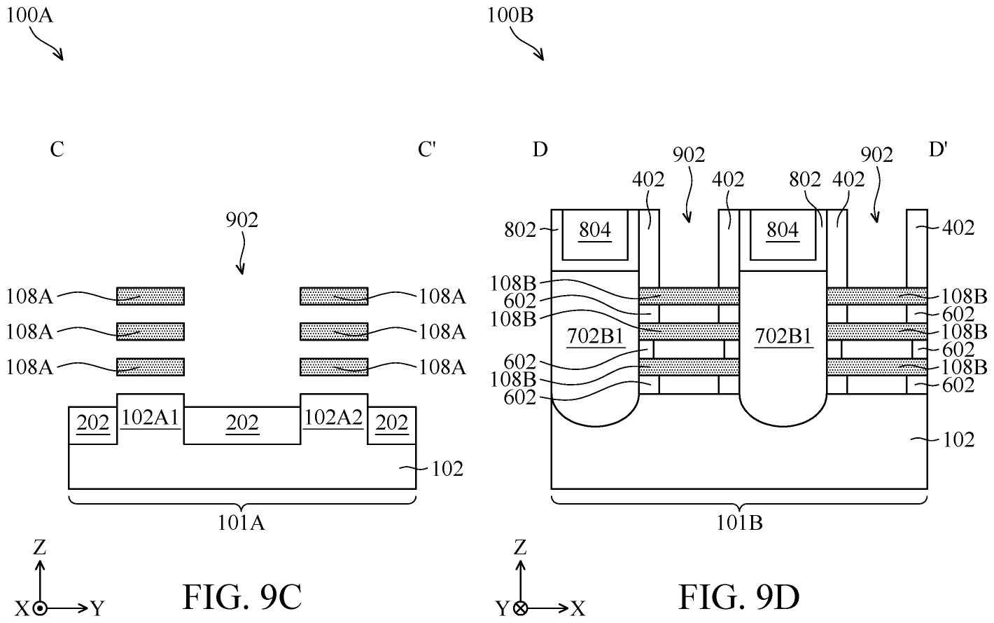

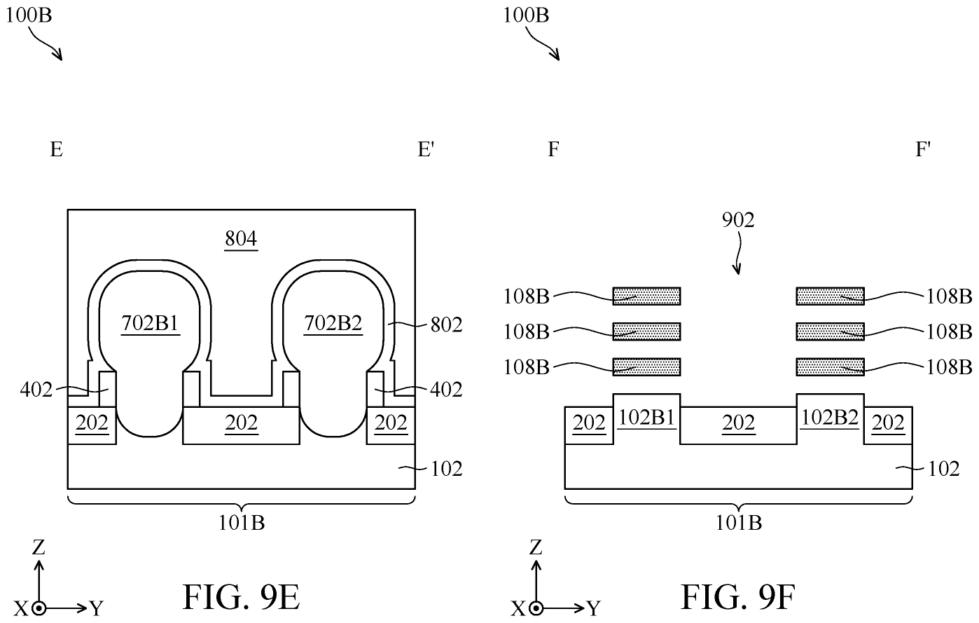

Referring to FIGS. 9A to 9F, the dummy gate structures 302 are selectively removed through any suitable photolithography and etching processes, in accordance with some embodiments. FIGS. 9A, 9B, and 9C are cross-sectional views of the semiconductor structure 100A along lines A-A′, B-B′, and C-C′ of FIG. 2A, respectively. FIGS. 9D, 9E, and 9F are cross-sectional views of the semiconductor structure 100B along lines D-D′, E-E′, and F-F′ of FIG. 2B, respectively.

In some embodiments, the photolithography process may include forming a photoresist layer (resist), exposing the resist to a pattern, performing a post-exposure bake process, and developing the resist to form a masking element, which exposes a region including the dummy gate structures 302. Then, the dummy gate structures 302 are selectively etched through the masking element. The gate spacers 402 may be used as the masking element or a part thereof. Etch selectivity may be achieved by selecting appropriate etching chemicals, and the dummy gate structures 302 may be removed without substantially affecting the CESL 802 and the ILD layer 804. The removal of the dummy gate structures 302 creates gate trenches 902, as shown in FIGS. 9A, 9C, 9D, and 9F. The gate trenches 902 exposes the top surfaces of the topmost semiconductor layers 108A and 108B that underlie the dummy gate structures 302.

Still referring to FIGS. 9A to 9F, the semiconductor layers 106A and 106B are selectively removed through the gate trenches 902, using a wet or dry etching process for example, in accordance with some embodiments. After the semiconductor layers 106A and 106B are selectively removed, the semiconductor layers 108A and 108B are exposed in the gate trenches 902 to form the nanostructures stacked on top of each other. The nanostructures serve as channels, channel layers, or channel members for resultant transistors. As such, the semiconductor layers 108A and 108B may be referred to as nanostructures. Such a process may also be referred to as a wire release process, a nanowire release process, a nanosheet release process, a nanowire formation process, a nanosheet formation process, or a wire formation process.

In some embodiments, the semiconductor layers 108A are stacked over and spaced apart from each other in the Z-direction, and the semiconductor layers 108B are stacked over and spaced apart from each other in the Z-direction. More specifically, the semiconductor layers 108A are suspended over and vertically arranged over the substrate 102 in the Z-direction and constitute vertical stacks, and the semiconductor layers 108B are suspended over and vertically arranged over the substrate 102 in the Z-direction and constitute vertical stacks. In some embodiments, the exposed semiconductor layers 108A and 108B extend longitudinally in the X-direction.

In some embodiments, thicknesses of the inner spacers 602 exposed in the gate trenches 902 in X-direction may be reduced during the removal of the semiconductor layers 106A and 106B. In some embodiments, after the removal of the semiconductor layers 106A and 106B, the thicknesses of the inner spacers 602 in the X-direction may be different. For example, in one stack of the inner spacers 602 directly under one gate spacer 402, the thickness of the second topmost one of the inner spacers 602 are less than other inner spacers 602. That is, pairs of inner spacers 602 formed between the second topmost one and the third topmost one of the semiconductor layers 106A and between the second topmost one and the third topmost one of the semiconductor layers 106B in the Z-direction have less thickness than other inner spacers 602.

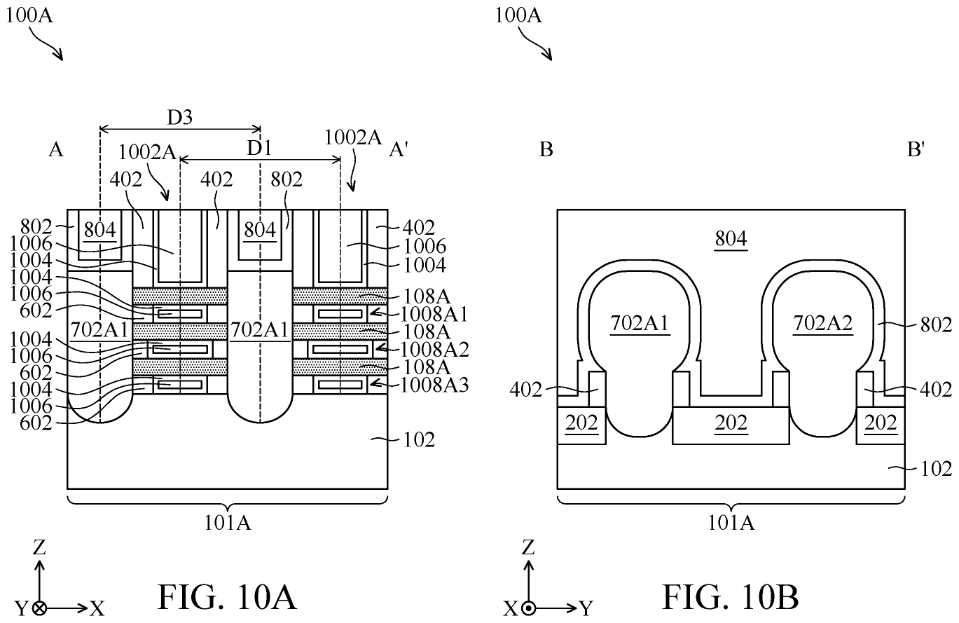

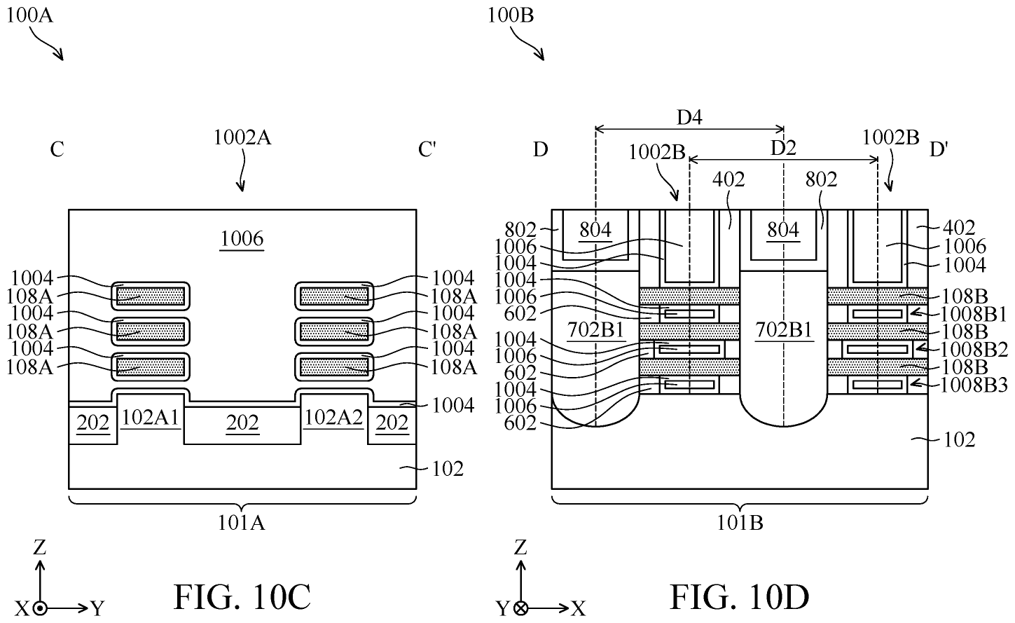

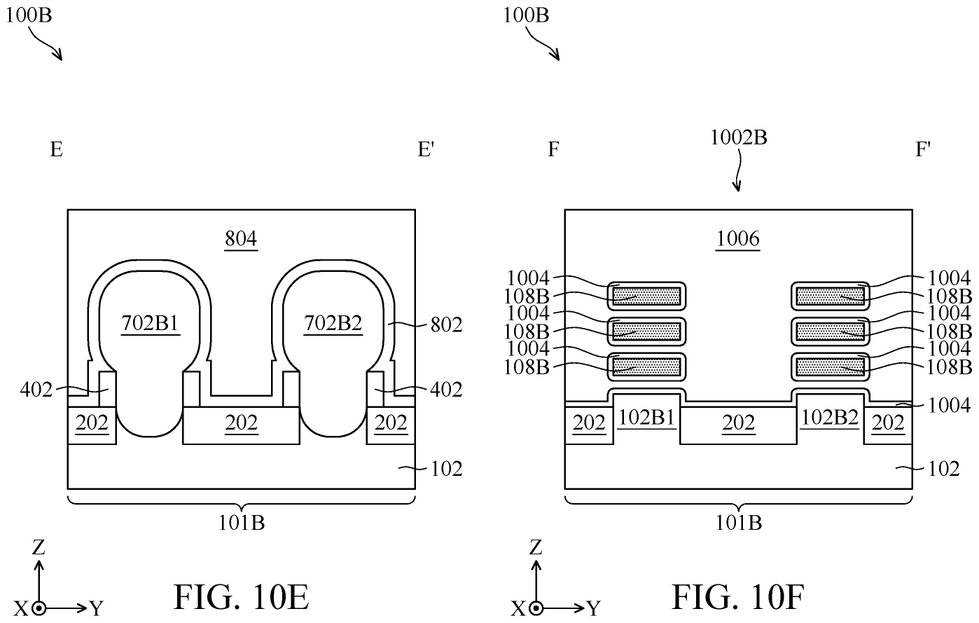

Referring to FIGS. 10A to 10F, gate structures 1002A and 1002B are formed in the gate trenches 902 to wrap around each of the exposed semiconductor layers 108A and 108B, respectively, in accordance with some embodiments. As such, the gate structures 1002A and 1002B replace the dummy gate structures 302. FIGS. 10A, 10B, and 10C are cross-sectional views of the semiconductor structure 100A along lines A-A′, B-B′, and C-C′ of FIG. 2A, respectively. FIGS. 10D, 10E, and 10F are cross-sectional views of the semiconductor structure 100B along lines D-D′, E-E′, and F-F′ of FIG. 2B, respectively.

In some embodiments, the gate structures 1002A and 1002B extend in the Y-direction. In some embodiments, the source/drain features 702A1 are formed on opposite sides of the gate structures 1002A in the X-direction, as shown in FIG. 10A. In some embodiments, the source/drain features 702A2 are formed on opposite sides of the gate structures 1002A in the X-direction. In some embodiments, the source/drain features 702B1 are formed on opposite sides of the gate structures 1002B in the X-direction, as shown in FIG. 10D. In some embodiments, the source/drain features 702B2 are formed on opposite sides of the gate structures 1002B in the X-direction.

In some embodiments, the gate structures 1002A and 1002B each includes a gate dielectric layer 1004 and a gate electrode layer 1006 over the gate dielectric layer 1004. In some embodiments, the gate dielectric layers 1004 are formed to wrap around semiconductor layers 108A and 108B in the gate trenches 902. In some embodiments, the gate dielectric layers 1004 are also formed on the sidewalls of the inner spacers 602 and the gate spacers 402, and over the top surfaces of the isolation structure 202 and the base fins 102A1, 102A2, 102B1, and 102B2.

The gate dielectric layers 1004 may include a dielectric material, such as SiOCN, SiOC, SiCN, SiO₂, SiN, SiC, or other suitable materials. In some embodiments, the gate dielectric layers 1004 may include a high-k dielectric material that has a dielectric constant greater than a dielectric constant of SiO₂, which is approximately 3.9. For example, the gate dielectric layers 1004 may include hafnium oxide (HfO₂), which has a dielectric constant in a range from about 18 to about 40. Alternatively, the gate dielectric layers 1004 may include other high-k dielectrics, such as TiO₂, HfZrO, Ta₂O₃, HfSiO₄, ZrO₂, ZrSiO₂, LaO, AlO, ZrO, TiO, Ta₂O₅, Y₂O₃, SrTiO₃ (STO), BaTiO₃ (BTO), BaZrO, HfLaO, HfSiO, LaSiO, AlSiO, HfTaO, HfTiO, (Ba,Sr)TiO₃ (BST), Al₂O₃, Si₃N₄, oxynitrides (SiON), combinations thereof, or other suitable materials. The gate dielectric layers 1004 may be formed by CVD, PVD, ALD, HDPCVD, MOCVD, RPCVD, PECVD, LPCVD, ALCVD, APCVD, FCVD, oxidation, and/or other suitable methods.

In some embodiments, the gate structures 1002A and 1002B each may further include an interfacial layer (not shown) that is formed to wrap around the exposed semiconductor layers 108A and 108B before the formation of the gate dielectric layers 1004, so that the gate dielectric layers 1004 are separated from the semiconductor layers 108A and 108B by the interfacial layers. In some embodiments, the interfacial layer may include a dielectric material such as silicon oxide (SiO₂), HfSiO, or silicon oxynitride (SiON). The interfacial layer may be formed by chemical oxidation, thermal oxidation, CVD, PVD, ALD, HDPCVD, MOCVD, RPCVD, PECVD, LPCVD, ALCVD, APCVD, FCVD, and/or other suitable method.

The gate electrode layers 1006 are formed to fill the remaining spaces of the gate trenches 902, and over the gate dielectric layers 1004 in such a way that the gate electrode layers 1006 wrap around the semiconductor layers 108A and 108B, the gate dielectric layer 1004, and the interfacial layers (if present). The gate electrode layers 1006 each may include a single layer or a multi-layer structure. In some embodiments, the gate electrode layers 1006 each may include a capping layer, a barrier layer, work function metal layers, and a fill material. The gate electrode layers 1006 may be formed using a deposition process such as CVD, PVD, ALD, HDPCVD, MOCVD, RPCVD, PECVD, LPCVD, ALCVD, APCVD, FCVD, or the like, although any suitable deposition process may be used. The capping layer may be formed of a metallic material such as TaN, Ti, TiAlN, TiAl, Pt, TaC, TaCN, TaSiN, Mn, Zr, TiN, Ru, Mo, WN, other metal oxides, metal nitrides, metal silicates, transition metal-oxides, transition metal-nitrides, transition metal-silicates, oxynitrides of metals, metal aluminates, zirconium silicate, zirconium aluminate, combinations of these, or the like.

The barrier layer may be formed of a material different from the capping layer. In some embodiments, the barrier layer may be formed of a material such as one or more layers of a metallic material. For example, the metallic material may be TiN, TaN, Ti, TiAlN, TiAl, Pt, TaC, TaCN, TaSiN, Mn, Zr, Ru, Mo, WN, other metal oxides, metal nitrides, metal silicates, transition metal-oxides, transition metal-nitrides, transition metal-silicates, oxynitrides of metals, metal aluminates, zirconium silicate, zirconium aluminate, combinations of these, or the like.

The work function layers may include conductive materials tuned to have a desired work function (e.g., an n-type work function or a p-type work function), such as n-type work function materials and/or p-type work function materials. In some embodiments, the n-type and p-type work function metal layers may include a material such as such as W, Al, Cu, TiN, Ti, TiAlN, TiAl, Pt, Ta, TaN, Co, Ni, TaC, TaCN, TaSiN, TaSi₂, NiSi₂, Mn, Zr, ZrSi₂, Ru, AlCu, Mo, MoSi₂, WN, other suitable work function materials, or combinations thereof. In some embodiments, the fill material may include a suitable conductive material, such as Al, W, and/or Cu.

Still referring to FIGS. 10A to 10F, the gate structures 1002A and 1002B may each be divided into an outer gate structure and an inner gate structure, in accordance with some embodiments. For example, the gate structures 1002A each has an outer gate structure that is over and an inner gate structure that is under the top surface of the topmost one of the semiconductor layers 108A. For example, the gate structures 1002B each has an outer gate structure that is over and an inner gate structure that is under the top surface of the topmost one of the semiconductor layers 108B. In some embodiments, for each of the gate structures 1002A of the semiconductor structure 100A, the inner gate structure includes a first inner portion 1008A1 between the topmost one and the second topmost one of the semiconductor layers 108A, a second inner portion 1008A2 between the second topmost one and the third topmost one of the semiconductor layers 108A, and a third inner portion 1008A3 between the third topmost one of the semiconductor layers 108A and the substrate 102. In some embodiments, the lengths of the first inner portion 1008A1 and the third inner portion 1008A3 are smaller than the length of the second inner portion 1008A2 in the X-direction, as shown in FIG. 10A.

In some embodiments, for each of the gate structures 1002B of the semiconductor structure 100B, the inner gate structure includes a first inner portion 1008B1 between the topmost one and the second topmost one of the semiconductor layers 108B, a second inner portion 1008B2 between the second topmost one and the third topmost one of the semiconductor layers 108B, and a third inner portion 1008B3 between the third topmost one of the semiconductor layers 108B and the substrate 102. In some embodiments, the lengths of the first inner portion 1008B1 and the third inner portion 1008B3 are smaller than the length of the second inner portion 1008B2 in the X-direction, as shown in FIG. 10D.

In some embodiments, the semiconductor structure 100A has a distance D1 between the middle line of one gate structure 1002A and the middle line of the adjacent gate structure 1002A in the X-direction, as shown in FIG. 10A. In some embodiments, the semiconductor structure 100B has a distance D2 between the middle line of one gate structure 1002B and the middle line of the adjacent gate structure 1002B in the X-direction, as shown in FIG. 10D. As described above, in some embodiments, the devices formed from the semiconductor structure 100A has smaller CPP and the devices formed from the semiconductor structure 100B has larger CPP. Therefore, the distance D1 of the semiconductor structure 100A is smaller than the distance D2 of the semiconductor structure 100B. In some embodiments, the distance D2 is greater than the distance D1 by more than 1 nm (nanometer). In certain embodiments, the distance D2 is greater than the distance D1 by more than 2 nm. In some embodiments, the distance D1 corresponds to the CPP of the semiconductor structure 100A, and the distance D2 corresponds to the CPP of the semiconductor structure 100B.

In other embodiments, the CPP may be defined by the distance between one source/drain feature and the adjacent source/drain feature. In some embodiments, the semiconductor structure 100A has a distance D3 between the middle line of one source/drain feature 702A1 (or 702A2) and the middle line of the adjacent source/drain feature 702A1 (or 702A2) in the X-direction, as shown in FIG. 10A. In some embodiments, the semiconductor structure 100B has a distance D4 between the middle line of one source/drain feature 702B1 (or 702B2) and the middle line of the adjacent source/drain feature 702B1 (or 702B2) in the X-direction, as shown in FIG. 10D. In some embodiments, the distance D3 of the semiconductor structure 100A is smaller than the distance D4 of the semiconductor structure 100B. In some embodiments, the distance D4 is greater than the distance D3 by more than 1 nm. In certain embodiments, the distance D4 is greater than the distance D3 by more than 2 nm.

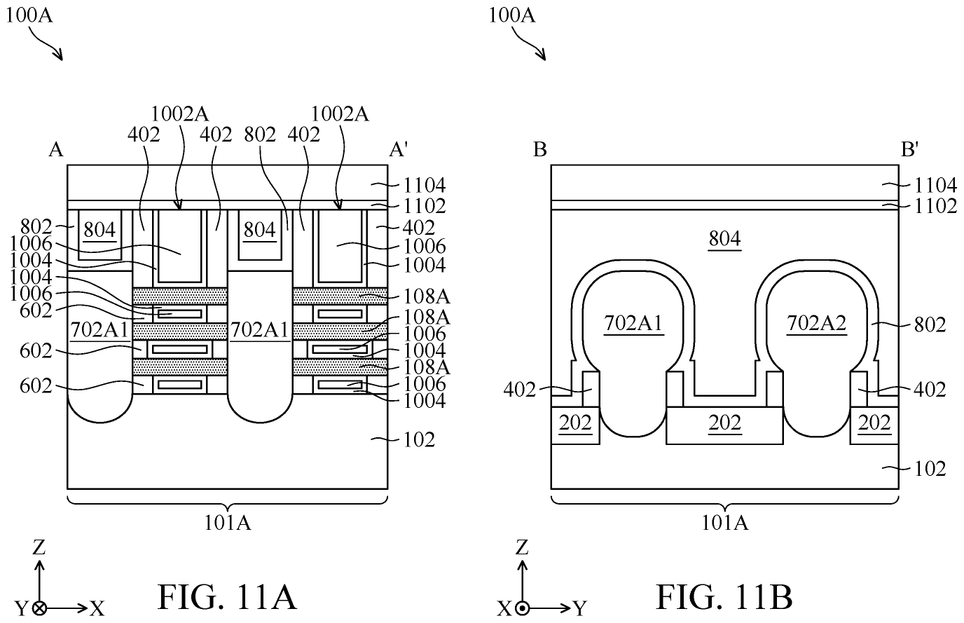

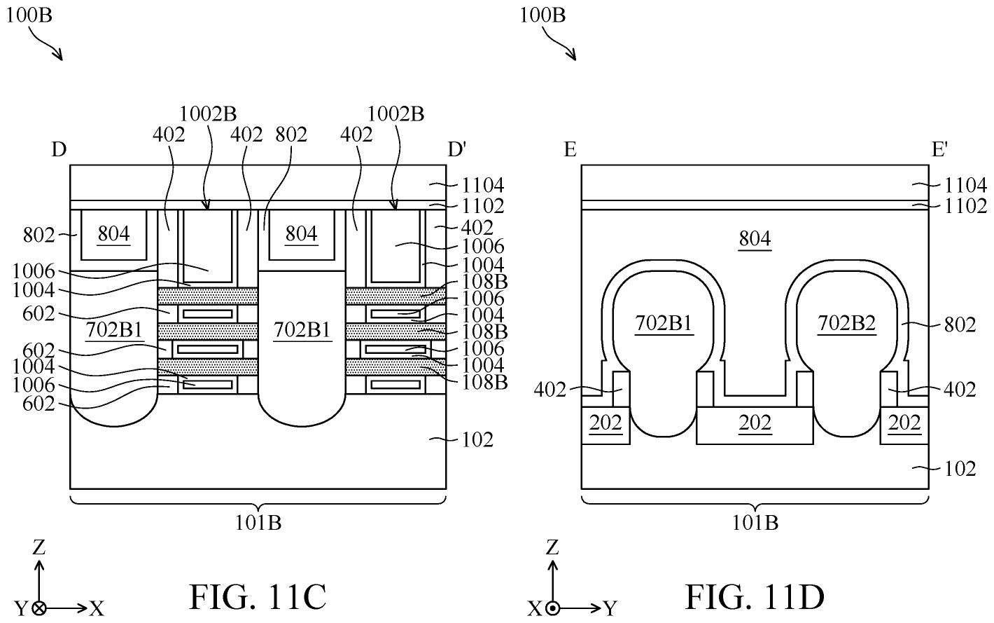

Referring to FIGS. 11A to 11D, an etch stop layer (ESL) 1102 and an ILD layer 1104 are formed over the semiconductor structures 100A and 100B, in accordance with some embodiments. FIGS. 11A and 11B are cross-sectional views of the semiconductor structure 100A along lines A-A′ and B-B′ of FIG. 2A, respectively. FIGS. 11C and 11D are cross-sectional views of the semiconductor structure 100B along lines D-D′ and E-E′ of FIG. 2B, respectively.

In some embodiments, the ESL 1102 is formed on the gate spacers 402, the CESL 802, the ILD layer 804, and the gate structures 1002A and 1002B, and the ILD layer 1104 is formed on the ESL 1102, as shown in FIGS. 11A to 11D. In some embodiments, the material and method used in forming the ESL 1102 and the ILD layer 1104 are the same as or similar to those of the CESL 802 and the ILD layer 804, respectively, and are not repeated herein.

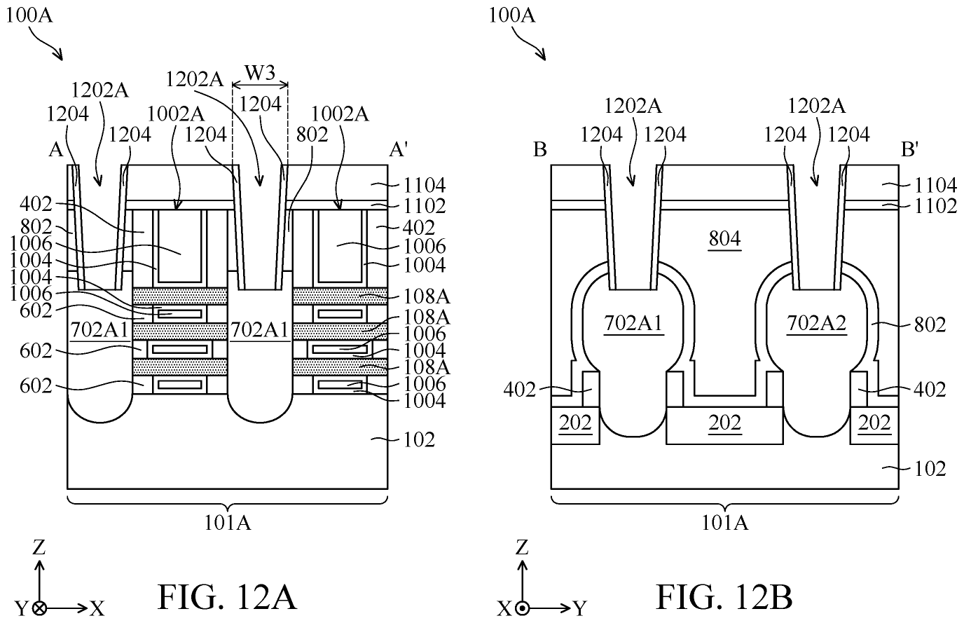

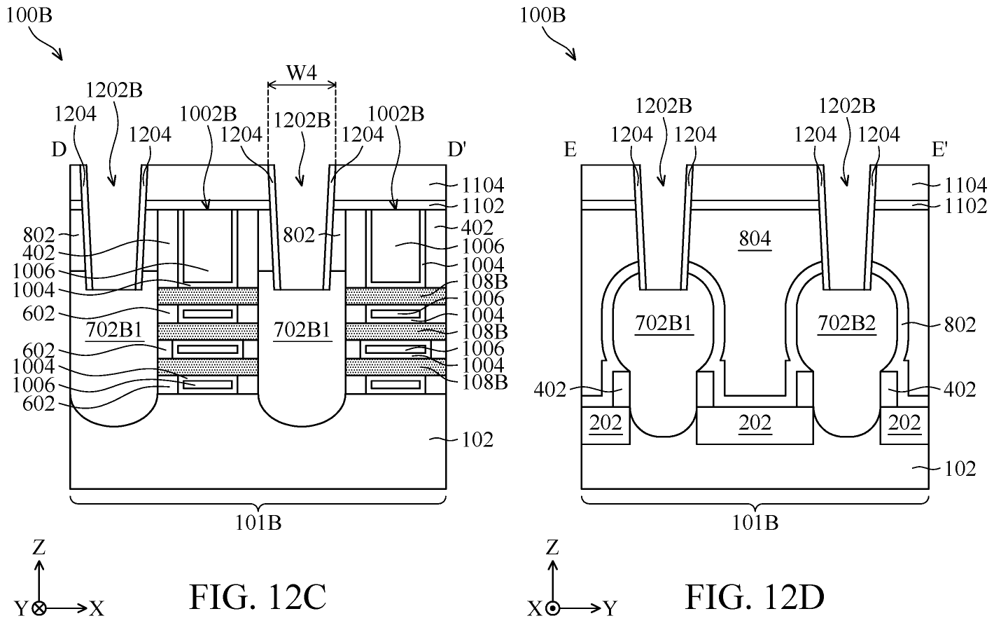

Referring to FIGS. 12A to 12D, trenches for accommodating source/drain contacts are formed to expose the source/drain features 702, in accordance with some embodiments. FIGS. 12A and 12B are cross-sectional views of the semiconductor structure 100A along lines A-A′ and B-B′ of FIG. 2A, respectively. FIGS. 12C and 12D are cross-sectional views of the semiconductor structure 100B along lines D-D′ and E-E′ of FIG. 2B, respectively.

In some embodiments, in the semiconductor structure 100A, trenches 1202A are formed to pass through the ILD layer 1104, the ESL 1102, the ILD layer 804, the CESL 802, and portions of the source/drain features 702A1 or 702A2, so as to expose the source/drain features 702A1 and 702A2, as shown in FIGS. 12A and 12B. In some embodiments, in the semiconductor structure 100B, trenches 1202B are formed to pass through the ILD layer 1104, the ESL 1102, the ILD layer 804, the CESL 802, and portions of the source/drain features 702B1 and 702B2, so as to expose the source/drain features 702B1 and 702B2, as shown in FIGS. 12C and 12D. In some embodiments, one or more photolithography and etching processes are performed to etch the ILD layer 1104, the ESL 1102, the ILD layer 804, and the CESL 802, and partially etch the source/drain features 702, so as to form the trenches 1202A that exposes the source/drain features 702A1 and 702A2 and form the trenches 1202B that exposes the source/drain features 702B1 and 702B2.

As described above, in some embodiments, the devices formed from the semiconductor structure 100A has smaller CPP and the devices formed from the semiconductor structure 100B has larger CPP. Therefore, in some embodiments, a width W3 of the trench 1202A is smaller than a width W4 of the trench 1202B in the X-direction, as shown in FIGS. 12A and 12C. In some embodiments, a width of the trench 1202A is smaller than a width of the trench 1202B in the Y-direction. In other embodiments, a width of the trench 1202A is the same as a width of the trench 1202B in the Y-direction.

Still referring to FIGS. 12A to 12D, sidewall dielectric layers 1204 are formed on sidewalls of the trenches 1202A and 1202B, in accordance with some embodiments. In other words, the sidewall dielectric layers 1204 are formed on surfaces of the ILD layer 1104, the ESL 1102, the ILD layer 804, the CESL 802, and the source/drain features 702 that form the sidewalls of the trenches 1202A and 1202B, while the horizontal surfaces of the source/drain features 702 are still exposed by the trenches 1202A and 1202B. In some embodiments, the material of the sidewall dielectric layer 1204 may include silicon nitride (Si₃N₄), silicon oxide (SiO₂), SiC, SiOC, SiON, SiCN, SiOCN, high-k dielectrics, other suitable materials, or combinations thereof.

In some embodiments, the sidewall dielectric layers 1204 may be formed by conformally depositing a material layer (containing dielectric material) on the surfaces of the ILD layer 1104 and the trenches 1202A and 1202B. Then, an anisotropic etching process is performed to remove horizontal portions of the material layer from the horizontal surfaces of the ILD layer 1104 and the source/drain features 702. After the anisotropic etching process, the portions of the material layer on the sidewall surfaces of the trenches 1202A and 1202B remain and become the sidewall dielectric layers 1204, and the horizontal surfaces of the source/drain features 702 are still exposed by the trenches 1202A and 1202B. In some embodiments, the anisotropic etching process is a dry (e.g., plasma) etching process. Additionally or alternatively, the formation of the sidewall dielectric layers 1204 may also involve chemical oxidation, thermal oxidation, CVD, PVD, ALD, HDPCVD, MOCVD, RPCVD, PECVD, LPCVD, ALCVD, APCVD, FCVD, and/or other suitable methods.

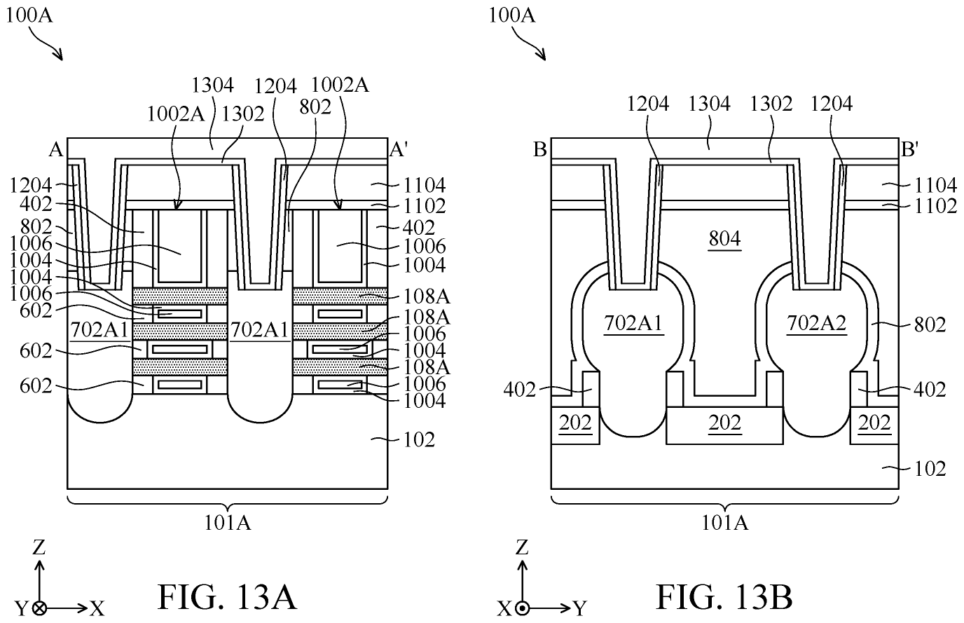

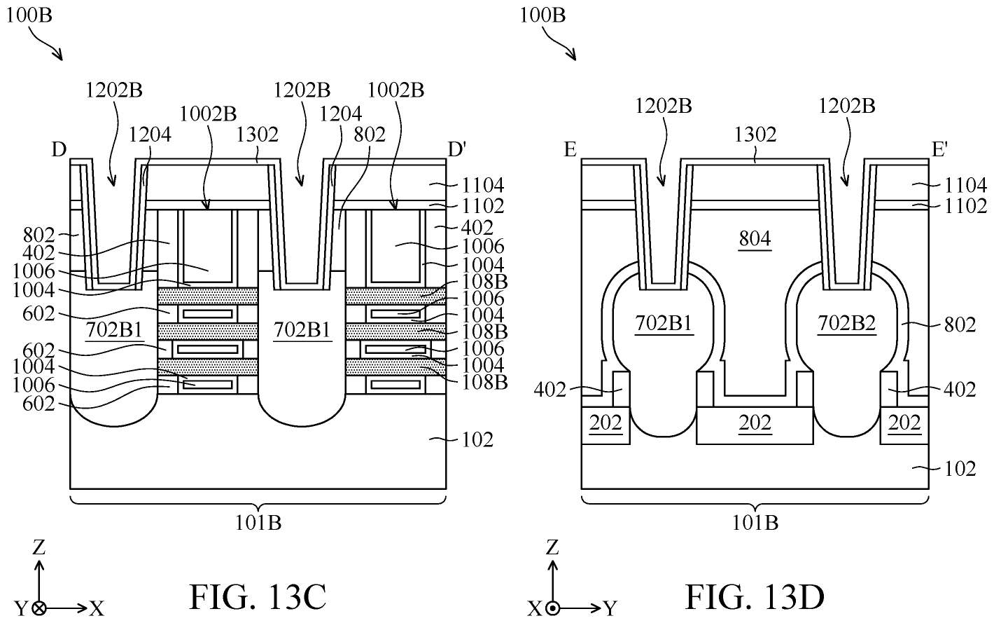

Referring to FIGS. 13A to 13D, a hard mask layer 1302 is formed on the semiconductor structures 100A and 100B, in accordance with some embodiments. FIGS. 13A and 13B are cross-sectional views of the semiconductor structure 100A along lines A-A′ and B-B′ of FIG. 2A, respectively. FIGS. 13C and 13D are cross-sectional views of the semiconductor structure 100B along lines D-D′ and E-E′ of FIG. 2B, respectively.

In some embodiments, in the semiconductor structure 100A, the hard mask layer 1302 is conformally formed on the top surface of the ILD layer 1104 and the sidewalls and the bottom surfaces of the trenches 1202A. That is, the top surface of the ILD layer 1104, the top surfaces and the sidewalls of the sidewall dielectric layers 1204, and the surfaces of the source/drain features 702A1 and 702A2 exposed by the trenches 1202A are covered by the hard mask layer 1302, as shown in FIGS. 13A and 13B. In some embodiments, in the semiconductor structure 100B, the hard mask layer 1302 is conformally formed on the top surface of the ILD layer 1104 and the sidewalls and the bottom surfaces of the trenches 1202B. That is, the top surface of the ILD layer 1104, the top surfaces and the sidewalls of the sidewall dielectric layers 1204, and the surfaces of the source/drain features 702B1 and 702B2 exposed by the trenches 1202B are covered by the hard mask layer 1302, as shown in FIGS. 13C and 13D.

In some embodiments, the material of the hard mask layer 1302 may include silicon nitride (Si₃N₄), SiON, SiCN, SiOCN, high-k dielectrics, other suitable materials, or combinations thereof. In some embodiments, the hard mask layer 1302 may be formed by CVD, PVD, ALD, HDPCVD, MOCVD, RPCVD, PECVD, LPCVD, ALCVD, APCVD, FCVD, or other suitable methods.

Still referring to FIGS. 13A to 13D, a patterned photoresist layer 1304 is formed over the semiconductor structure 100A, in accordance with some embodiments. In some embodiments, the patterned photoresist layer 1304 is formed in the region 101A without being formed in the region 101B, so as to cover the semiconductor structure 100A and expose the semiconductor structure 100B. More specifically, the patterned photoresist layer 1304 covers a portion of the hard mask layer 1302 formed in the semiconductor structure 100A. In some embodiments, the patterned photoresist layer 1304 fills the remaining spaces of the trenches 1202A, as shown in FIGS. 13A and 13B. In some embodiments, the patterned photoresist layer 1304 is formed by a photolithography process that includes forming a photoresist layer, exposing the photoresist layer to a pattern, performing a post-exposure bake process, and developing the photoresist layer to form the patterned photoresist layer 1304, which covers the semiconductor structure 100A and exposes the semiconductor structure 100B.

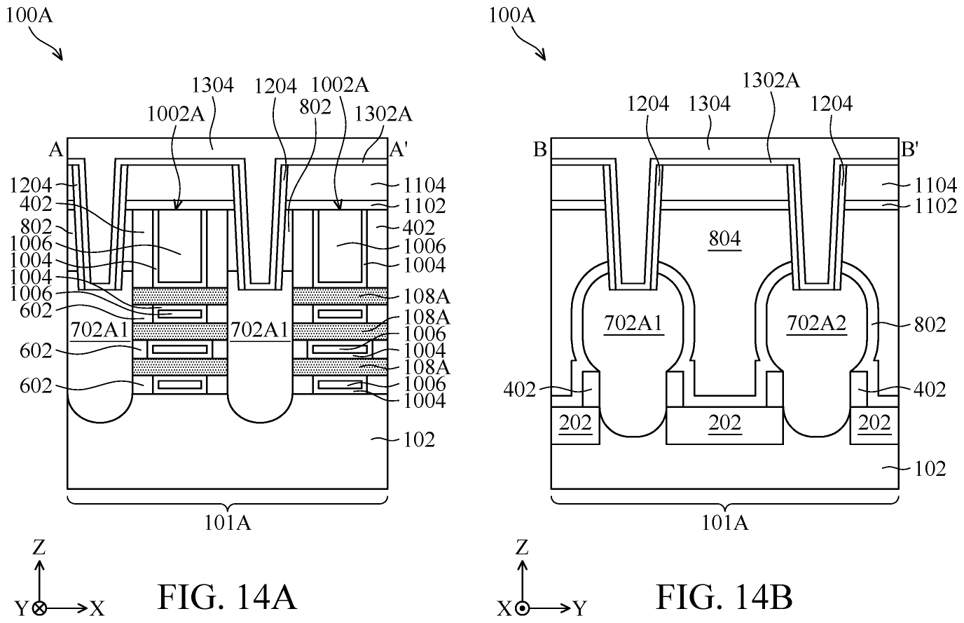

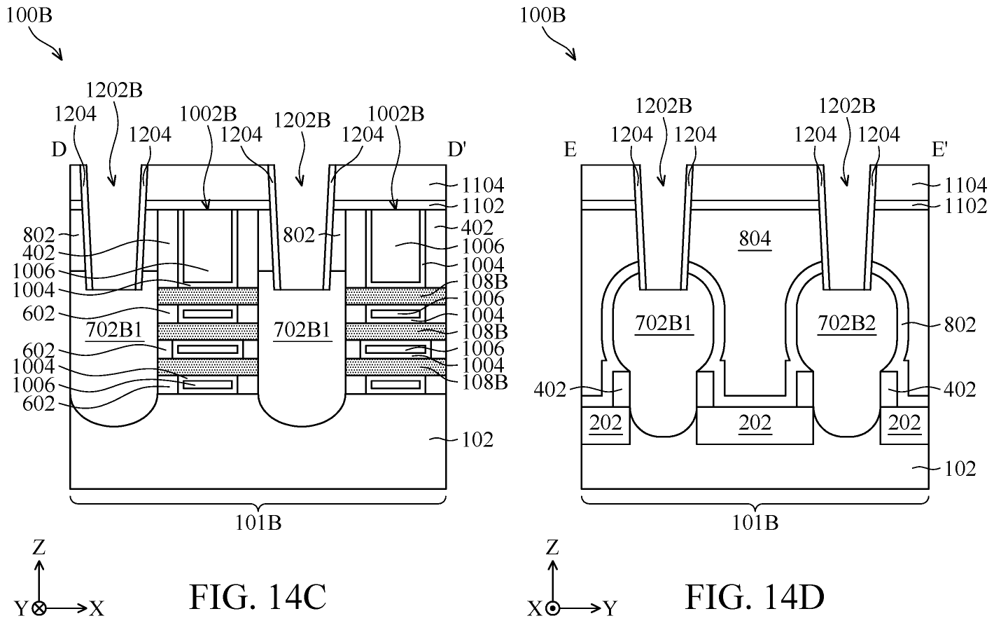

Referring to FIGS. 14A to 14D, a portion of hard mask layer 1302 formed in the semiconductor structure 100B is removed, in accordance with some embodiments. FIGS. 14A and 14B are cross-sectional views of the semiconductor structure 100A along lines A-A′ and B-B′ of FIG. 2A, respectively. FIGS. 14C and 14D are cross-sectional views of the semiconductor structure 100B along lines D-D′ and E-E′ of FIG. 2B, respectively.

In some embodiments, the portion of the hard mask layer 1302 formed in the semiconductor structure 100B is removed by one or more etching processes. The etching processes may be selective etching processes that selectively etch the hard mask layer 1302, with minimal etching (or substantially no etching) of the ILD layer 1104, the sidewall dielectric layers 1204, and the source/drain features 702B1 and 702B2. The selective etching process may be a dry etching process, a wet etching process, other suitable etching process, or combinations thereof. In some embodiments, due to being covered by the patterned photoresist layer 1304, the portion of the hard mask layer 1302 formed in the semiconductor structure 100A is protected from the etching processes and remains after the etching processes.

In some embodiments, after the etching processes, the portion of the hard mask layer 1302 formed in the semiconductor structure 100B is removed, and the portion of the hard mask layer 1302 formed in the semiconductor structure 100A remains and becomes a hard mask layer 1302A. As such, the semiconductor structure 100A is still covered by the hard mask layer 1302A (and the patterned photoresist layer 1304), while the semiconductor structure 100B is not covered by the hard mask layer 1302, as shown in FIGS. 14A to 14D. After the etching processes, the surfaces of the source/drain features 702B1 and 702B2 are exposed by the trenches 1202B, as shown in FIGS. 14C and 14D.

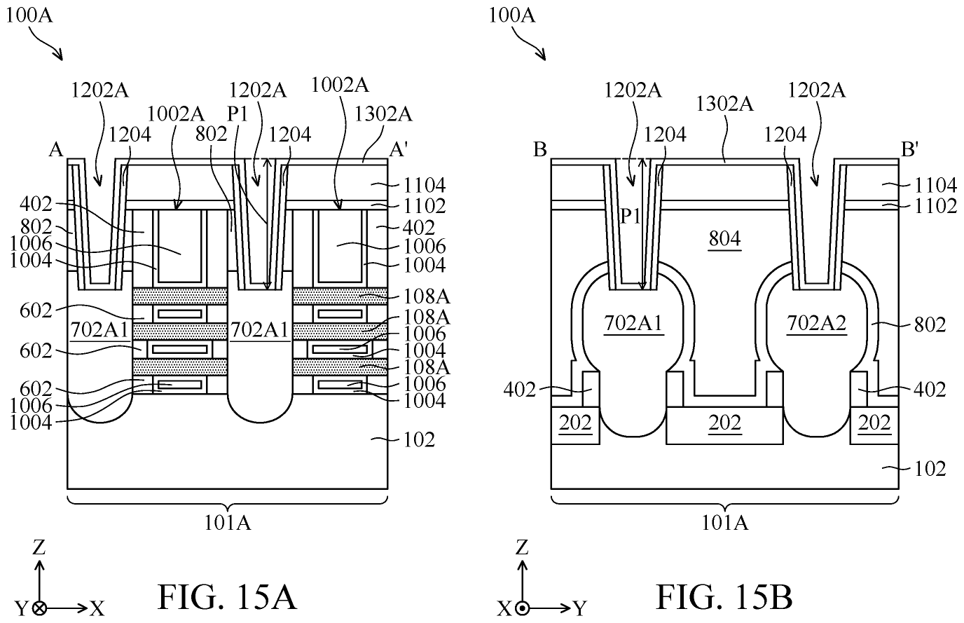

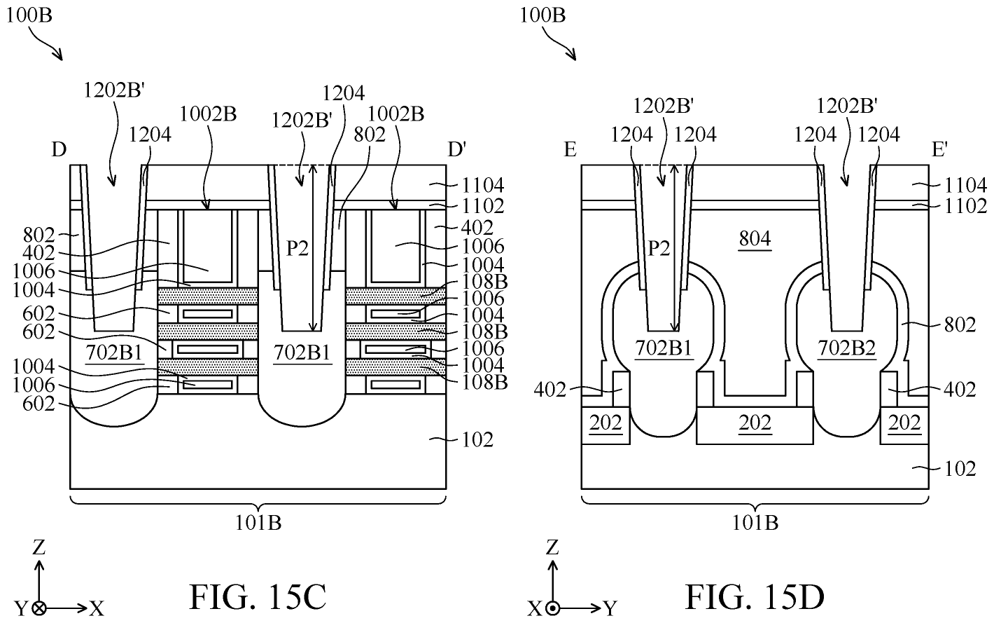

Referring to FIGS. 15A to 15D, the patterned photoresist layer 1304 is removed and the trenches 1202B are further extended, in accordance with some embodiments. FIGS. 15A and 15B are cross-sectional views of the semiconductor structure 100A along lines A-A′ and B-B′ of FIG. 2A, respectively. FIGS. 15C and 15D are cross-sectional views of the semiconductor structure 100B along lines D-D′ and E-E′ of FIG. 2B, respectively.

In some embodiments, the patterned photoresist layer 1304 is removed from the semiconductor structure 100A, for example, using a photoresist ashing or stripping process. After removing the patterned photoresist layer 1304, the semiconductor structure 100A is still covered by the hard mask layer 1302A. More specifically, the trenches 1202A are still covered by the hard mask layer 1302A, such that the surfaces of the source/drain features 702A1 and 702A2 exposed by the trenches 1202A are still covered by the hard mask layer 1302A.

Still referring to FIGS. 15A to 15D, the source/drain features 702B1 and 702B2 are partially etched to further extend the trenches 1202B downward in the Z-direction, in accordance with some embodiments. After etching, the extended trenches 1202B can be referred to as trenches 1202B′, which have depths that are greater than depths of the trenches 1202B in the Z-direction. In some embodiments, the trenches 1202B are extended by one or more etching processes. The etching processes may be selective etching processes that selectively etch the source/drain features 702B1 and 702B2, with minimal etching (or substantially no etching) of the ILD layer 1104, the sidewall dielectric layers 1204, and the hard mask layer 1302A. The selective etching process may be a dry etching process, a wet etching process, other suitable etching process, or combinations thereof.

In some embodiments, due to being covered by the hard mask layer 1302A, the elements in the semiconductor structure 100A, especially the source/drain features 702A1 and 702A2, are protected from the etching processes, such that the trenches 1202A are not extended in the Z-direction during the etching processes. Therefore, in the Z-direction, the depths P1 of the trenches 1202A keep the same and are smaller than the depths P2 of the trenches 1202B′, as shown in FIGS. 15A to 15D. In some embodiments, the depth P2 is greater than the depth P1 by more than 4 nm. In other embodiments, the depth P2 is greater than the depth P1 by 0.5 nm to 4 nm.

In some embodiments, the trenches 1202A extend downward into the height of the topmost one of the second semiconductor layers 108A in the Z-direction. In some embodiments, the trenches 1202B′ extend downward into the height of the second topmost one of the second semiconductor layers 108B in the Z-direction. In certain embodiments, the trenches 1202B′ extend downward into the height of the third topmost one of the second semiconductor layers 108B in the Z-direction. In other embodiments, the trenches 1202A and 1202B′ may each has any suitable depth in the Z-direction.

In other embodiments, the patterned photoresist layer 1304 is removed after extending the trenches 1202B into the trenches 1202B′. That is, the source/drain features 702B1 and 702B2 are partially etched while both the hard mask layer 1302A and the patterned photoresist layer 1304 exist. In some embodiments, due to being covered by both the hard mask layer 1302A and the patterned photoresist layer 1304, the elements in the semiconductor structure 100A, especially the source/drain features 702A1 and 702A2, are protected from the etching processes, such that the trenches 1202A are not extended in the Z-direction during the etching processes.

In some embodiments, additional sidewall dielectric layers are formed on newly-generated sidewalls of the trenches 1202B′. The newly-generated sidewalls are generated due to extending the trench 1202B into the trenches 1202B′, and may be sidewalls of the trenches 1202B′ that are not covered by the sidewall dielectric layers 1204 and expose the surfaces of the source/drain features 702B1 and 702B2. In some embodiments, the additional sidewall dielectric layers also cover the existing sidewall dielectric layers 1204. In other embodiments, the sidewall dielectric layers 1204 are formed after forming the trenches 1202B′, such that the sidewall dielectric layers 1204 cover the entire sidewalls of the trenches 1202B′.

Referring to FIGS. 16A to 16D, the hard mask layer 1302A is removed and the source/drain contacts are formed, in accordance with some embodiments. FIGS. 16A and 16B are cross-sectional views of the semiconductor structure 100A along lines A-A′ and B-B′ of FIG. 2A, respectively. FIGS. 16C and 16D are cross-sectional views of the semiconductor structure 100B along lines D-D′ and E-E′ of FIG. 2B, respectively.

In some embodiments, the hard mask layer 1302A is removed by one or more etching processes. The etching processes may be selective etching processes that selectively etch the hard mask layer 1302A, with minimal etching (or substantially no etching) of the ILD layer 1104, the sidewall dielectric layers 1204, and the source/drain features 702. The selective etching process may be a dry etching process, a wet etching process, other suitable etching process, or combinations thereof. In some embodiments, after the etching processes, the trenches 1202A are exposed, and thus the source/drain features 702A1 and 702A2 are exposed by the trenches 1202A.

Still referring to FIGS. 16A to 16D, the silicide layers 1602A are formed on the exposed surfaces of the source/drain features 702A1 and 702A2 in the trenches 1202A, and the silicide layers 1602B are formed on the exposed surfaces of the source/drain features 702B1 and 702B2 in the trenches 1202B′, in accordance with some embodiments. In some embodiments, the silicide layers 1602A are formed by depositing metal layers on the source/drain features 702A1 and 702A2, and heating the workpiece 100 to cause constituents of the source/drain features 702A1 and 702A2 to react with metal constituents of the metal layers. Similarly, the silicide layers 1602B may be formed by depositing metal layers on the source/drain features 702B1 and 702B2, and heating the workpiece 100 to cause constituents of the source/drain features 702B1 and 702B2 to react with metal constituents of the metal layers.

In some embodiments, the silicide layers 1602A and 1602B may include titanium silicide (TiSi), nickel silicide (NiSi), tungsten silicide (WSi), nickel-platinum silicide (NiPtSi), nickel-platinum-germanium silicide (NiPtGeSi), nickel-germanium silicide (NiGeSi), ytterbium silicide (YbSi), platinum silicide (PtSi), iridium silicide (IrSi), erbium silicide (ErSi), cobalt silicide (CoSi), or other suitable compounds. In some embodiments, the material of the silicide layers 1602A formed on the source/drain features 702A1 are different from the material of the silicide layer 1602A formed on the source/drain features 702A2, and the silicide layers 1602B formed on the source/drain features 702B1 are different from the material of the silicide layer 1602B formed on the source/drain features 702B2. For example, the silicide layers 1602A formed on the source/drain features 702A1 and the silicide layers 1602B formed on the source/drain features 702B1 may include compounds with metal(s), Si, and Ge, and the silicide layers 1602A formed on the source/drain features 702A2 and the silicide layers 1602B formed on the source/drain features 702B2 may include compounds with metal(s) and Si.

Still referring to FIGS. 16A to 16D, the source/drain contacts 1604A and 1604B are formed in the trenches 1202A and 1202B′, respectively, in accordance with some embodiments. In some embodiments, a conductive material is deposited in the trenches 1202A and 1202B′ and on the silicide layers 1602A and 1602B by a deposition process, so as to form the source/drain contacts 1604A and 1604B. That is, the trenches 1202A are filled with the conductive material to form the source/drain contacts 1604A, and the trenches 1202B′ are filled with the conductive material to form the source/drain contacts 1604B. In some embodiments, the source/drain contacts 1604A partially extend into the source/drain features 702A1 and 702A2 of the semiconductor structure 100A, as shown in FIGS. 16A and 16B. In some embodiments, the source/drain contacts 1604A are in contact with and electrically connected to the source/drain features 702A1 and 702A2. In some embodiments, the source/drain contacts 1604B partially extend into the source/drain features 702B1 and 702B2 of the semiconductor structure 100B, as shown in FIGS. 16C and 16D. In some embodiments, the source/drain contacts 1604B are in contact with and electrically connected to the source/drain features 702B1 and 702B2.

In some embodiments, the silicide layers 1602A are formed on the bottoms of the source/drain contacts 1604A, and formed between the source/drain contacts 1604A and the source/drain features 702A1 or 702A2, as shown in FIGS. 16A and 16B. In some embodiments, the silicide layers 1602B are formed on the bottoms and sidewalls of the lower portions of the source/drain contacts 1604B, and formed between the source/drain contacts 1604B and the source/drain features 702B1 or 702B2, such that the lower portions of the source/drain contacts 1604B are surrounded by the silicide layers 1602B, as shown in FIGS. 16C and 16D.

In some embodiments, the sidewall dielectric layers 1204 are formed on sidewalls of the source/drain contacts 1604A, such that the source/drain contacts 1604A are surrounded and separated from the ILD layer 1104, the ESL 1102, and the CESL 802 by the sidewall dielectric layers 1204, as shown in FIGS. 16A and 16B. In some embodiments, the sidewall dielectric layers 1204 are formed on sidewalls of the upper portions of the source/drain contacts 1604B, such that the upper portions of the source/drain contacts 1604B are surrounded and separated from the ILD layer 1104, the ESL 1102, and the CESL 802 by the sidewall dielectric layers 1204, as shown in FIGS. 16C and 16D.

In some embodiments, since the source/drain contacts 1604A are formed in the trenches 1202A, the source/drain contacts 1604A have the depths P1 that are the same as the trenches 1202A, as shown in FIGS. 16A and 16B. In some embodiments, since the source/drain contacts 1604B are formed in the trenches 1202B′, the source/drain contacts 1604B have the depths P2 that are the same as the trenches 1202B′, as shown in FIGS. 16C and 16D. As described above, in some embodiments, the depth P2 is greater than the depth P1 by more than 4 nm. In other embodiments, the depth P2 is greater than the depth P1 by 0.5 nm to 4 nm. In some embodiments, the depths P3 that the source/drain contacts 1604A extend inside the source/drain features 702A1 or 702A2 and the depths P4 that the source/drain contacts 1604B extend inside the source/drain features 702B1 or 702B2 are in a range from about 4 nm to about 50 nm. In some embodiments, the depth P4 is greater than the depth P3 by more than 4 nm. In other embodiments, the depth P4 is greater than the depth P3 by 0.5 nm to 4 nm.

Referring to FIGS. 17A to 17D, fabrication stage shown in FIGS. 17A to 17D follows the fabrication stage shown in FIGS. 12A to 12D. In FIGS. 17A to 17D, hard mask layer 1702 is formed, in accordance with some embodiments. FIGS. 17A and 17B are cross-sectional views of the semiconductor structure 100A along lines A-A′ and B-B′ of FIG. 2A, respectively. FIGS. 17C and 17D are cross-sectional views of the semiconductor structure 100B along lines D-D′ and E-E′ of FIG. 2B, respectively.

In some embodiments, the hard mask layer 1702 is conformally formed over the semiconductor structure 100A and the semiconductor structure 100B. That is, the top surface of the ILD layer 1104, the top surfaces and the sidewalls of the sidewall dielectric layers 1204, and the surfaces of the source/drain features 702A1, 702A2, 702B1, and 702B2 exposed by the trenches 1202A and 1202B are covered by the hard mask layer 1702. In some embodiments, since the trenches 1202A have the smaller width W3, the hard mask layer 1702 is merged in the trenches 1202A. In some embodiments, the merged hard mask layer 1702 fills the remaining portions of the trenches 1202A, as shown in FIGS. 17A and 17B. In some embodiments, since the trenches 1202B have the larger width W4, the portions of the hard mask layer 1702 formed in the trenches 1202B are in the form of a layer, as shown in FIGS. 17C and 17D. That is, there are some spaces of the trenches 1202B are remained after forming the hard mask layer 1702. In some embodiments, the distance D2 is greater than the distance D1 by more than 2 nm.

In some embodiments, the material and method used in forming the hard mask layer 1702 are the same as or similar to those of the hard mask layer 1302, and are not repeated herein.

Referring to FIGS. 18A to 18D, the hard mask layer 1702 is partially removed and the trenches 1202B are further extended, in accordance with some embodiments. FIGS. 18A and 18B are cross-sectional views of the semiconductor structure 100A along lines A-A′ and B-B′ of FIG. 2A, respectively. FIGS. 18C and 18D are cross-sectional views of the semiconductor structure 100B along lines D-D′ and E-E′ of FIG. 2B, respectively.

In some embodiments, the hard mask layer 1702 is etched by one or more etching processes. The etching processes may be selective etching processes that selectively etch the hard mask layer 1702, with minimal etching (or substantially no etching) of the ILD layer 1104, the sidewall dielectric layers 1204, and the source/drain features 702. The selective etching process may be a dry etching process, a wet etching process, other suitable etching process, or combinations thereof.

In some embodiments, since the hard mask layer 1702 is merged in the trenches 1202A, portions of the hard mask layer 1702 are still remained in the trenches 1202A of the semiconductor structure 100A after the etching processes. The remaining portions of the hard mask layer 1702 remained in the trenches 1202A may be referred to as hard mask layers 1702A. In some embodiments, after the etching processes, the surfaces of the source/drain features 702A1 and 702A2 exposed by the trenches 1202A are still covered by the hard mask layers 1702A, as shown in FIGS. 18A and 18B. In some embodiments, after the etching processes, the portion of the hard mask layer 1702 formed in the semiconductor structure 100B is removed, and the source/drain features 702B1 and 702B2 are exposed by the trenches 1202B, as shown in FIGS. 18C and 18D.

In the embodiments where the hard mask layer 1702 is applied, since the hard mask layers 1702A are still remained to cover the surfaces of the source/drain features 702A1 and 702A2 after the etching processes without additional photolithography process, the patterned photoresist layer 1304 can be omitted. Therefore, the related costs of process for forming the patterned photoresist layer 1304 (e.g., costs of time, photoresist, photomask, developer, etc.) can be saved.

Still referring to FIGS. 18A to 18D, the source/drain features 702B1 and 702B2 are partially etched to further extend the trenches 1202B downward in the Z-direction, in accordance with some embodiments. After etching, the extended trenches 1202B can be referred to as trenches 1202B′, which have depths that are greater than depths of the trenches 1202B in the Z-direction. In some embodiments, the trenches 1202B are extended by one or more etching processes. The etching processes may be selective etching processes that selectively etch the source/drain features 702B1 and 702B2, with minimal etching (or substantially no etching) of the ILD layer 1104, the sidewall dielectric layers 1204, and the hard mask layers 1702A. The selective etching process may be a dry etching process, a wet etching process, other suitable etching process, or combinations thereof.

In some embodiments, due to being covered by the hard mask layer 1702A, the source/drain features 702A1 and 702A2 are protected from the etching processes, such that the trenches 1202A are not extended in the Z-direction during the etching processes. Therefore, in the Z-direction, the depths P1 of the trenches 1202A keep the same and are smaller than the depths P2 of the trenches 1202B′, as shown in FIGS. 18A to 18D. In some embodiments, the depth P2 is greater than the depth P1 by more than 4 nm. In other embodiments, the depth P2 is greater than the depth P1 by 0.5 nm to 4 nm.

In some embodiments, additional sidewall dielectric layers are formed on newly-generated sidewalls of the trenches 1202B′. The newly-generated sidewalls are generated due to extending the trench 1202B into the trenches 1202B′, and may be sidewalls of the trenches 1202B′ that are not covered by the sidewall dielectric layers 1204 and expose the surfaces of the source/drain features 702B1 and 702B2. In some embodiments, the additional sidewall dielectric layers also cover the existing sidewall dielectric layers 1204. In other embodiments, the sidewall dielectric layers 1204 are formed after forming the trenches 1202B′, such that the sidewall dielectric layers 1204 cover the entire sidewalls of the trenches 1202B′.

Referring to FIGS. 19A to 19D, the hard mask layers 1702A are removed, in accordance with some embodiments. FIGS. 19A and 19B are cross-sectional views of the semiconductor structure 100A along lines A-A′ and B-B′ of FIG. 2A, respectively. FIGS. 19C and 19D are cross-sectional views of the semiconductor structure 100B along lines D-D′ and E-E′ of FIG. 2B, respectively.

In some embodiments, the hard mask layers 1702A are removed by one or more etching processes. The etching processes may be selective etching processes that selectively etch the hard mask layers 1702A, with minimal etching (or substantially no etching) of the ILD layer 1104, the sidewall dielectric layers 1204, and the source/drain features 702. The selective etching process may be a dry etching process, a wet etching process, other suitable etching process, or combinations thereof. In some embodiments, after the etching processes, the trenches 1202A are exposed, and thus the source/drain features 702A1 and 702A2 are exposed by the trenches 1202A.

After the fabrication stage shown in FIGS. 19A to 19D, referring back to FIGS. 16A to 16D, the source/drain contacts 1604A and 1604B are formed, in accordance with some embodiments. As described above, the silicide layers 1602A are formed on the exposed surfaces of the source/drain features 702A1 and 702A2 in the trenches 1202A, and the silicide layers 1602B are formed on the exposed surfaces of the source/drain features 702B1 and 702B2 in the trenches 1202B′, in accordance with some embodiments. As described above, the source/drain contacts 1604A and 1604B are formed in the trenches 1202A and 1202B′, respectively, in accordance with some embodiments.

In some embodiments, since the source/drain contacts 1604A are formed in the trenches 1202A, the source/drain contacts 1604A have the depths P1 that are the same as the trenches 1202A, as shown in FIGS. 16A and 16B. In some embodiments, since the source/drain contacts 1604B are formed in the trenches 1202B′, the source/drain contacts 1604B have the depths P2 that are the same as the trenches 1202B′, as shown in FIGS. 16C and 16D. As described above, in some embodiments, the depth P2 is greater than the depth P1 by more than 4 nm. In other embodiments, the depth P2 is greater than the depth P1 by 0.5 nm to 4 nm.

The embodiments discussed in FIGS. 1 to 19D provide methods to form structures that have shallower S/D contacts (e.g., the source/drain contacts 1604A) in small CPP devices (e.g., the semiconductor structure 100A) and deeper S/D contacts (e.g., the source/drain contacts 1604B) in large CPP devices (e.g., the semiconductor structure 100B). In this way, it can avoid the contact between the S/D contacts and the first epitaxial layer in the small CPP devices, and thus avoid the increased Rcsd in the small CPP devices. Moreover, it can also avoid the contact between the S/D contacts and the inner gate portions, and thus avoid the negative impact on the yield. On the other hand, the deeper S/D contacts can be implemented in the large CPP devices to increase the contact area between the S/D contacts and the S/D features, and thus the Rcsd in the large CPP devices can be reduced. As a result, the device performances in the small CPP devices and the large CPP devices can be optimized individually and simultaneously.

FIGS. 20A and 20B are X-Z cross-sectional views of a semiconductor structure 200A and a semiconductor structure 200B, respectively, in accordance with alternative embodiments of the present disclosure. The semiconductor structure 200A shown in FIG. 20A may be similar to the semiconductor structure 100A shown in FIG. 16A, except the source/drain features 702A1 shown in FIG. 16A are replaced by source/drain features 2002A1 shown in FIG. 20A. The semiconductor structure 200B shown in FIG. 20B may be similar to the semiconductor structure 100B shown in FIG. 16C, except the source/drain features 702B1 shown in FIG. 16C are replaced by source/drain features 2002B1 shown in FIG. 20B.

In some embodiments, each of the source/drain features 2002A1 includes an undoped epitaxial layer 2004A1 over the substrate 102, a first epitaxial layer 2006A1 over the undoped epitaxial layer 2004A1 and end portions of the semiconductor layers 108A, and a second epitaxial layer 2008A1 over the first epitaxial layer 2006A1, as shown in FIG. 20A. In some embodiments, the first epitaxial layer 2006A1 is in a discontinuous form that includes a bottom portion on the undoped epitaxial layer 2004A1 and a plurality of ellipse portions on the ends of the semiconductor layers 108A, as shown in FIG. 20A. In some embodiments, each of the ellipse portions of the first epitaxial layer 2006A1 has a thickness in the X-direction that is in a range from about 2 nm to about 10 nm. In other embodiments, the first epitaxial layer 2006A1 is in the form of a continuous layer.

In some embodiments, each of the source/drain features 2002B1 includes an undoped epitaxial layer 2004B1 over the substrate 102, a first epitaxial layer 2006B1 over the undoped epitaxial layer 2004B1 and end portions of the semiconductor layers 108B, and a second epitaxial layer 2008B1 over the first epitaxial layer 2006B1, as shown in FIG. 20B. In some embodiments, the first epitaxial layer 2006B1 is in a discontinuous form that includes a bottom portion on the undoped epitaxial layer 2004B1 and a plurality of ellipse portions on the ends of the semiconductor layers 108B, as shown in FIG. 20B. In some embodiments, each of the ellipse portions of the first epitaxial layer 2006B1 has a thickness in the X-direction that is in a range from about 2 nm to about 10 nm. In other embodiments, the first epitaxial layer 2006B1 is in the form of a continuous layer.

In some embodiments, the undoped epitaxial layers 2004A1 and 2004B1 are substantially free of dopants. The undoped epitaxial layers 2004A1 and 2004B1 may include silicon, germanium, silicon germanium, other suitable semiconductor materials, or combinations thereof. In some embodiments, the undoped epitaxial layers 2004A1 and 2004B1 include silicon that is substantially free of n-type dopants and p-type dopants. In some embodiments, the first epitaxial layers 2006A1 and 2006B1 and the second epitaxial layers 2008A1 and 2008B1 include the same semiconductor material but with different constituent concentrations. The semiconductor material can include silicon, germanium, silicon germanium, other suitable semiconductor material, or combinations thereof.

In the embodiments where the source/drain features 2002A1 and 2002B1 are configured to form p-type GAA transistors, the first epitaxial layers 2006A1 and 2006B1 and the second epitaxial layers 2008A1 and 2008B1 include p-doped silicon germanium but with different p-type concentrations. For example, the first epitaxial layers 2006A1 and 2006B1 may have a p-type dopant concentration (e.g., a boron concentration) of about 1×10²⁰/cm³ to about 5×10²⁰/cm³, and the second epitaxial layers 2008A1 and 2008B1 may have a p-type dopant concentration (e.g., boron concentration) of about 5×10²⁰/cm³ to about 2×10²¹/cm³.

In the embodiments where the source/drain features 2002A1 and 2002B1 are configured to form n-type GAA transistors, the first epitaxial layers 2006A1 and 2006B1 and the second epitaxial layers 2008A1 and 2008B1 include n-doped silicon but with different n-type concentrations. For example, the first epitaxial layers 2006A1 and 2006B1 may have an n-type dopant concentration (e.g., a phosphorous concentration or an arsenic concentration) of about 1×10²⁰/cm³ to about 5×10²⁰/cm³, and the second epitaxial layers 2008A1 and 2008B1 may have an n-type dopant concentration (e.g., a phosphorous concentration or an arsenic concentration) of about 5×10²⁰/cm³ to about 2×10²¹/cm³.

In some embodiments, the undoped epitaxial layer 2004A1 is epitaxially grown from the semiconductor surface of the substrate 102 on the bottom of the source/drain trench 502A using an epitaxial growth process. In some embodiments, the first epitaxial layer 2006A1 is epitaxially grown from the undoped epitaxial layer 2004A1 and the end portions of the semiconductor layers 108A exposed by the trench 502A using an epitaxial growth process. In some embodiments, the second epitaxial layer 2008A1 is epitaxially grown from the first epitaxial layer 2006A1 using an epitaxial growth process.

In some embodiments, the undoped epitaxial layer 2004B1 is epitaxially grown from the semiconductor surface of the substrate 102 on the bottom of the source/drain trench 502B using an epitaxial growth process. In some embodiments, the first epitaxial layer 2006B1 is epitaxially grown from the undoped epitaxial layer 2004B1 and the end portions of the semiconductor layers 108B exposed by the trench 502B using an epitaxial growth process. In some embodiments, the second epitaxial layer 2008B1 is epitaxially grown from the first epitaxial layer 2006B1 using an epitaxial growth process. The epitaxial growth process for forming the undoped epitaxial layer 2004A1 and 2004B1, the first epitaxial layer 2006A1 and 2006B1, and the second epitaxial layer 2008A1 and 2008B1 may be VPE, MOCVD, MBE, or other deposition processes, such as CVD, LPCVD, PECVD, ALD, UHVCVD, RPCVD, combinations thereof, or the like.

As shown in the embodiments of FIGS. 20A and 20B, since the S/D features (e.g., the source/drain features 2002B1) of the large CPP devices (e.g., the semiconductor structure 200B) have large widths, the S/D contacts (e.g., the source/drain contacts 1604B) can extend downward without contacting the first epitaxial layer of the S/D features (e.g., the first epitaxial layer 2006B1). Therefore, the deeper S/D contacts (e.g., the source/drain contacts 1604B) can be implemented in the large CPP devices and used to increase the contact area between the S/D contacts and the S/D features, and thus the Rcsd in the large CPP devices can be reduced. On the other hand, since the S/D features have large widths, even if the positions of the S/D contacts are shifted during the process, the deeper S/D contacts will still not contact the inner gate portions (e.g., the second inner portion 1008B2). Therefore, the negative impact on the yield can be avoided.

In some embodiments, the semiconductor structures may further include bottom isolation layers between the source/drain features and the substrates. FIGS. 21A to 23B illustrate the embodiments where the semiconductor structures include the bottom isolation layers.

FIGS. 21A and 21B are Y-Z cross-sectional views of a semiconductor structure 300A and a semiconductor structure 300B, respectively, in accordance with alternative embodiments of the present disclosure. The semiconductor structure 300A shown in FIG. 21A may be similar to the semiconductor structure 100A shown in FIG. 16B, except bottom isolation layers 2100 are interposed between the source/drain features 702A2 and the substrate 102. The semiconductor structure 300B shown in FIG. 21B may be similar to the semiconductor structure 100B shown in FIG. 16D, except bottom isolation layers 2100 are interposed between the source/drain features 702B2 and the substrate 102.

In some embodiments, the bottom isolation layers are formed in the n-type GAA transistors and are omitted in the p-type GAA transistors. In the embodiments where the source/drain features 702A2 and 702B2 are configured to form n-type GAA transistors, the bottom isolation layers 2100 are formed in the bottom portions of the source/drain trenches 502A used to accommodate the source/drain features 702A2 and the source/drain trenches 502B used to accommodate the source/drain features 702B2. Then, the source/drain features 702A2 and 702B2 are formed on the bottom isolation layers 2100. That is, the bottom isolation layers 2100 are formed between the source/drain features 702A2 and the substrate 102 and between the source/drain features 702B2 and the substrate 102, as shown in FIGS. 21A and 21B.

FIGS. 22A and 22B are Y-Z cross-sectional views of a semiconductor structure 400A and a semiconductor structure 400B, respectively, in accordance with alternative embodiments of the present disclosure. The semiconductor structure 400A shown in FIG. 22A may be similar to the semiconductor structure 100A shown in FIG. 16B, except bottom isolation layers 2200 are interposed between the source/drain features 702A1 and the substrate 102. The semiconductor structure 400B shown in FIG. 22B may be similar to the semiconductor structure 100B shown in FIG. 16D, except bottom isolation layers 2200 are interposed between the source/drain features 702B1 and the substrate 102.

In some embodiments, the bottom isolation layers are formed in the p-type GAA transistors and are omitted in the n-type GAA transistors. In the embodiments where the source/drain features 702A1 and 702B1 are configured to form p-type GAA transistors, the bottom isolation layers 2200 are formed in the bottom portions of the source/drain trenches 502A used to accommodate the source/drain features 702A1 and the source/drain trenches 502B used to accommodate the source/drain features 702B1. Then, the source/drain features 702A1 and 702B1 are formed on the bottom isolation layers 2200. That is, the bottom isolation layers 2200 are formed between the source/drain features 702A1 and the substrate 102 and between the source/drain features 702B1 and the substrate 102, as shown in FIGS. 22A and 22B.

FIGS. 23A and 23B are Y-Z cross-sectional views of a semiconductor structure 500A and a semiconductor structure 500B, respectively, in accordance with alternative embodiments of the present disclosure. The semiconductor structure 500A shown in FIG. 23A may be similar to the semiconductor structure 100A shown in FIG. 16B, except bottom isolation layers 2300 are interposed between the source/drain features 702A1 and 702A2 and the substrate 102. The semiconductor structure 500B shown in FIG. 23B may be similar to the semiconductor structure 100B shown in FIG. 16D, except bottom isolation layers 2300 are interposed between the source/drain features 702B1 and 702B2 and the substrate 102.

In some embodiments, the bottom isolation layers are formed in both the p-type GAA transistors and the n-type GAA transistors. In the embodiments where the source/drain features 702A1 and 702B1 are configured to form p-type GAA transistors and the source/drain features 702A2 and 702B2 are configured to form n-type GAA transistors, the bottom isolation layers 2300 are formed in the bottom portions of the source/drain trenches 502A and 502B. Then, the source/drain features 702A1, 702A2, 702B1, and 702B2 are formed on the bottom isolation layers 2300. That is, the bottom isolation layers 2300 are formed between the source/drain features 702A1 and the substrate 102, between the source/drain features 702A2 and the substrate 102, between the source/drain features 702B1 and the substrate 102, and between the source/drain features 702B2 and the substrate 102, as shown in FIGS. 23A and 23B.

In some embodiments, each of the bottom isolation layers 2100, 2200, and 2300 may include silicon nitride (Si₃N₄), silicon oxide (SiO₂), SiC, SiOC, SiON, SiCN, SiOCN, high-k dielectrics, other suitable materials, or combinations thereof. In some embodiments, the bottom isolation layers 2100, 2200, and 2300 may be deposited by CVD, PVD, ALD, HDPCVD, MOCVD, RPCVD, PECVD, LPCVD, ALCVD, APCVD, other suitable methods, or combinations thereof.

Although FIGS. 4A to 20B show that two vertical stacks of the nanostructures (e.g., semiconductor layers 108A or 108B) and two corresponding gate structures (e.g., gate structures 1002A or 1002B) and two source/drain features (e.g., source/drain features 702A1/2002A1 or 702B1/2002B1) are formed in one fin structure (e.g., fin structure 112A1 or 112B1), which are for illustrative purposes only and are not intended to limit the present disclosure. For example, an additional source/drain feature 702A1 and corresponding elements (e.g., source/drain contact, silicide layer) may be formed in the fin structure 112A1, such that each vertical stack of the semiconductor layers 108A are between two source/drain feature 702A1, as shown in FIG. 24A. For example, an additional source/drain feature 702B1 and corresponding elements (e.g., source/drain contact, silicide layer) may be formed in the fin structure 112B1, such that each vertical stack of the semiconductor layers 108B are between two source/drain feature 702B1, as shown in FIG. 24B. However, the present disclosure is not limited to two vertical stacks of the nanostructures and two or three source/drain features, the number of the vertical stacks of the nanostructures and the number of the source/drain features depend on the design requirements.

The embodiments disclosed herein relate to semiconductor structures and their forming methods, and more particularly to methods and semiconductor structures that include forming a small CPP device with shallower S/D contacts and a large CPP device with deeper S/D contacts. In this way, it can avoid the contact between the S/D contacts and the first epitaxial layers in the small CPP device, and thus avoid the increased Rcsd in the small CPP device. Moreover, it can also avoid the contact between the S/D contacts and the inner gate portions, and thus avoid the negative impact on the yield. On the other hand, the deeper S/D contacts implemented in the large CPP device can increase the contact area between the S/D contacts and the S/D features without contacting the first epitaxial layers, and thus the Rcsd in the large CPP device can be reduced. As a result, the device performances in the small CPP device and the large CPP device can be optimized individually and simultaneously.

In one exemplary aspect, the present disclosure is directed to a method of forming a semiconductor structure. The method includes forming a first fin structure and a second fin structure in a first region and a second region of a substrate, respectively; forming a first source/drain feature and a second source/drain feature in the first fin structure; and forming a third source/drain feature and a fourth source/drain feature in the second fin structure. Each of the first fin structure and the second fin structure includes first semiconductor layers and second semiconductor layers alternately stacked. The method further includes forming a first gate structure between the first source/drain feature and the second source/drain feature to wrap around each of the second semiconductor layers in the first fin structure; forming a second gate structure between the third source/drain feature and the fourth source/drain feature to wrap around each of the second semiconductor layers in the second fin structure; and forming a first trench over and exposing the first source/drain feature, and forming a second trench over and exposing the third source/drain feature. The method further includes forming a hard mask layer in the first region of the substrate to cover a surface of the first trench; etching the third source/drain feature to extend the second trench in a Z-direction; removing the hard mask layer; and depositing a conductive material in the first trench and the second trench to form a first source/drain contact and a second source/drain contact.

In another exemplary aspect, the present disclosure is directed to a method of forming a semiconductor structure. The method includes forming first semiconductor layers and second semiconductor layers over a substrate; patterning the first semiconductor layers and the second semiconductor layers to form a first fin structure and a second fin structure; forming a first source/drain feature and a second source/drain feature in the first fin structure that are spaced apart from each other in an X-direction; and forming a third source/drain feature and a fourth source/drain feature in the second fin structure that are spaced apart from each other in the X-direction. The first semiconductor layers and the second semiconductor layers are alternately stacked in a Z-direction. The method further includes forming a first gate structure between the first source/drain feature and the second source/drain feature and a second gate structure between the third source/drain feature and the fourth source/drain feature; forming a first trench over and exposing the first source/drain feature; forming a second trench over and exposing the third source/drain feature; and forming a hard mask layer in the first trench and the second trench. The method further includes removing a second portion of the hard mask layer formed in the second trench; etching the third source/drain feature to extend the second trench in a Z-direction; removing the hard mask layer; and depositing a conductive material in the first trench and the second trench to form a first source/drain contact and a second source/drain contact.

In yet another exemplary aspect, the present disclosure is directed to a semiconductor structure. The semiconductor structure includes a first transistor in a first region of a substrate and a second transistor in a second region of the substrate. The first transistor includes first nanostructures spaced apart from each other in a Z-direction; a first gate structure wrapped around each of the first nanostructures; first source/drain features, attached to opposite sides of the first nanostructures in an X-direction; and first source/drain contacts partially extending into and electrically connected to the first source/drain features. The second transistor includes second nanostructures spaced apart from each other in a Z-direction; a second gate structure wrapped around each of the second nanostructures; second source/drain features attached to opposite sides of the second nanostructures in an X-direction; and second source/drain contacts partially extending into and electrically connected to the first source/drain features. A second depth of the second source/drain contact is greater than a first depth of the first source/drain contact in the Z-direction. A second width of the second source/drain feature is greater than a first width of the first source/drain feature in the X-direction.

In yet another exemplary aspect, the present disclosure is directed to a method of forming a semiconductor structure. The method includes forming a first fin structure and a second fin structure in a first region and a second region of a substrate, respectively; forming a first dummy gate structure and a second dummy gate structure on the first fin structure and the second fin structure, respectively; forming a first source/drain feature and a second source/drain feature on opposite sides of the first dummy gate structure in an X-direction; and forming a third source/drain feature and a fourth source/drain feature on opposite sides of the second dummy gate structure in the X-direction. Each of the first fin structure and the second fin structure includes first semiconductor layers and second semiconductor layers alternately stacked. The method further includes forming a first trench over and exposing the first source/drain feature; and forming a second trench over and exposing the third source/drain feature; forming a hard mask layer in the first region and the second region; and removing a second portion of the hard mask layer formed in the second region to expose the second trench. The first trench is covered by a first portion of the hard mask layer formed in the first region. The method further includes etching the third source/drain feature to extend the second trench in a Z-direction; and removing the first portion of the hard mask layer formed in the first region.

In some embodiments, the method further includes before removing the second portion of the hard mask layer, forming a photoresist layer in the first region and the second region; patterning the photoresist layer to remove a portion of the photoresist layer from the second region, such that a remaining portion of the photoresist layer remains in the first region; and after the patterning of the photoresist layer, performing an etching process to etch the third source/drain feature to extend the second trench. The first trench is covered by the first portion of the hard mask layer and the remaining portion of the photoresist layer.

In some embodiments, a first width of the first source/drain feature is smaller than a second width of the third source/drain feature in the X-direction; and after the extending of the second trench, a second depth of the second trench is greater than a first depth of the first trench in the Z-direction.

In some embodiments, the method further includes forming source/drain trenches on the opposite sides of the first dummy gate structure and on the opposite sides of the second dummy gate structure in the X-direction; forming bottom isolation layers in bottom portions of the source/drain trenches; and forming the first source/drain feature, the second source/drain feature, the third source/drain feature, and the first source/drain feature in the source/drain trenches and on the bottom isolation layers.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of forming a semiconductor structure, comprising:
forming a first fin structure and a second fin structure in a first region and a second region of a substrate, respectively, wherein each of the first fin structure and the second fin structure comprises first semiconductor layers and second semiconductor layers alternately stacked;
forming a first source/drain feature and a second source/drain feature in the first fin structure, and forming a third source/drain feature and a fourth source/drain feature in the second fin structure;
forming a first gate structure between the first source/drain feature and the second source/drain feature to wrap around each of the second semiconductor layers in the first fin structure, and forming a second gate structure between the third source/drain feature and the fourth source/drain feature to wrap around each of the second semiconductor layers in the second fin structure;
forming a first trench over and exposing the first source/drain feature, and forming a second trench over and exposing the third source/drain feature;
forming a hard mask layer in the first region of the substrate to cover a surface of the first trench;
etching the third source/drain feature to extend the second trench in a Z-direction;
removing the hard mask layer; and
depositing a conductive material in the first trench and the second trench to form a first source/drain contact and a second source/drain contact.

2. The method of claim 1, further comprising:
forming a hard mask material layer in the first region and the second region;
forming a photoresist layer on the hard mask material layer in the first region; and
removing the hard mask material layer from the second region to form the hard mask layer in the first region, such that the first trench is covered by the hard mask layer and the third source/drain feature is exposed by the second trench.

3. The method of claim 1, further comprising:
forming a dielectric layer in the first trench and the second trench; and
removing horizontal portions of the dielectric layer to form sidewall dielectric layers on sidewalls of the first trench and the second trench.

4. The method of claim 1, further comprising:
forming a contact etch stop layer on the first source/drain feature, the second source/drain feature, the third source/drain feature, and the fourth source/drain feature, and forming an interlayer dielectric (ILD) layer on the contact etch stop layer,
wherein the forming of the first trench and the second trench is performed by etching through the contact etch stop layer and the ILD layer.

5. The method of claim 1,
wherein a first width of the first source/drain feature is smaller than a second width of the third source/drain feature in an X-direction; and
wherein after the extending of the second trench, a second depth of the second trench is greater than a first depth of the first trench in the Z-direction.

6. The method of claim 1, further comprising:
forming a fifth source/drain feature in the first fin structure and a third gate structure between the second source/drain feature and the fifth source/drain feature; and
forming a sixth source/drain feature in the second fin structure and a fourth gate structure between the fourth source/drain feature and the sixth source/drain feature,
wherein a first distance between a middle line of the first gate structure and a middle line of the third gate structure is smaller than a second distance between a middle line of the second gate structure and a middle line of the fourth gate structure in an X-direction.

7. The method of claim 1, further comprising:
forming a first dummy gate structure and a second dummy gate structure on the first fin structure and the second fin structure, respectively;
forming source/drain trenches on opposite sides of the first dummy gate structure and on opposite sides of the second dummy gate structure; and
forming the first source/drain feature, the second source/drain feature, the third source/drain feature, and the fourth source/drain feature in the source/drain trenches.

8. The method of claim 1, wherein the forming of each of the first source/drain feature, the second source/drain feature, the third source/drain feature, and the fourth source/drain feature comprises:
forming source/drain trenches in the first fin structure and the second fin structure;
forming a first epitaxial layer on end portions of the second semiconductor layers exposed by the source/drain trenches; and
forming a second epitaxial layer to fill the source/drain trenches.

9. A method of forming a semiconductor structure, comprising:
forming first semiconductor layers and second semiconductor layers over a substrate, wherein the first semiconductor layers and the second semiconductor layers are alternately stacked in a Z-direction;
patterning the first semiconductor layers and the second semiconductor layers to form a first fin structure and a second fin structure;
forming a first source/drain feature and a second source/drain feature in the first fin structure that are spaced apart from each other in an X-direction, and forming a third source/drain feature and a fourth source/drain feature in the second fin structure that are spaced apart from each other in the X-direction;
forming a first gate structure between the first source/drain feature and the second source/drain feature and a second gate structure between the third source/drain feature and the fourth source/drain feature;
forming a first trench over and exposing the first source/drain feature, and forming a second trench over and exposing the third source/drain feature;
forming a hard mask layer in the first trench and the second trench;
removing a second portion of the hard mask layer formed in the second trench;
etching the third source/drain feature to extend the second trench in a Z-direction;
removing the hard mask layer; and
depositing a conductive material in the first trench and the second trench to form a first source/drain contact and a second source/drain contact.

10. The method of claim 9,
wherein a first portion of the hard mask layer formed in the first trench is merged together in the first trench to fill the first trench; and
wherein the second portion of the hard mask layer covers the second trench in form of a layer.

11. The method of claim 10,
wherein the removing of the second portion of the hard mask layer comprises performing an etching process;
wherein after the etching process, the first portion of the hard mask layer merged in the first trench remains in the first trench, and the second portion of the hard mask layer is removed.

12. The method of claim 9,
wherein a first width of the first trench is smaller than a second width of the second trench in the X-direction; and
wherein a first distance between a middle line of the first source/drain feature and a middle line of the second source/drain feature is smaller than a second distance between a middle line of the third source/drain feature and a middle line of the fourth source/drain feature in the X-direction.

13. The method of claim 9, wherein after the extending of the second trench, a second depth of the second trench is greater than a first depth of the first trench in the Z-direction, wherein the second depth is at least 4 nanometers greater than the first depth.

14. The method of claim 9, wherein the forming of the first gate structure comprises:
removing the first semiconductor layers in the first fin structure to form a first gate trench; and
forming the first gate structure in the first gate trench to wrap around each of the second semiconductor layers in the first fin structure.

15. The method of claim 14,
wherein the first gate structure comprises a first inner portion and a second inner portion;
wherein the first inner portion is between a topmost one of the second semiconductor layers and a second topmost one of the second semiconductor layers in the first fin structure, and the second inner portion is between the second topmost one of the second semiconductor layers and a third topmost one of the second semiconductor layers in the first fin structure; and
wherein a first length of the first inner portion is smaller than a second length of the second inner portion in the X-direction.

16. The method of claim 9, further comprising:
forming a first silicide on a surface of the first source/drain feature exposed by the first trench; and
after the extending of the second trench, forming a second silicide layer on a surface of the third source/drain feature exposed by the second trench.

17. A semiconductor structure, comprising:
a first transistor in a first region of a substrate, the first transistor comprising:
first nanostructures, spaced apart from each other in a Z-direction;
a first gate structure, wrapped around each of the first nanostructures;
first source/drain features, attached to opposite sides of the first nanostructures in an X-direction; and
first source/drain contacts, partially extending into and electrically connected to the first source/drain features;
a second transistor in a second region of the substrate, the second transistor comprising:
second nanostructures, spaced apart from each other in a Z-direction;
a second gate structure, wrapped around each of the second nanostructures;
second source/drain features, attached to opposite sides of the second nanostructures in an X-direction; and
second source/drain contacts, partially extending into and electrically connected to the first source/drain features,
wherein a second depth of the second source/drain contact is greater than a first depth of the first source/drain contact in the Z-direction,
wherein a second width of the second source/drain feature is greater than a first width of the first source/drain feature in the X-direction.

18. The semiconductor structure of claim 17, wherein a second distance between middle lines of the adjacent two second source/drain features is greater than a first distance between middle lines of the adjacent two first source/drain features in the X-direction.

19. The semiconductor structure of claim 17,
wherein the first gate structure comprises a first inner portion and a second inner portion;
wherein the first inner portion is between a topmost one of the first nanostructures and a second topmost one of the first nanostructures, and the second inner portion is between the second topmost one of the first nanostructures and a third topmost one of the first nanostructures; and
wherein a second length of the second inner portion is greater than a first length of the first inner portion in the X-direction.

20. The semiconductor structure of claim 17,
wherein each of the first source/drain features comprises a first epitaxial layer formed on end portions of the first nanostructures, and a second epitaxial layer formed on the first epitaxial layer; and
wherein each of the second source/drain features comprises a third epitaxial layer formed on end portions of the second nanostructures, and a fourth epitaxial layer formed on the third epitaxial layer.
